(19) United States
(12) Patent Application Publication
(10) Pub. No.: US 2026/0184985 A1
(43) Pub. Date: Jul. 2, 2026

(54) ORGANIC LIGHT-EMITTING DEVICE AND DISPLAY APPARATUS

(71) Applicant: BOE Technology Group Co., Ltd., Beijing (CN)

(72) Inventors: Rongrong GAO, Beijing (CN); Bingyan LIANG, Beijing (CN); Lei CHEN, Beijing (CN); Dongxu ZHANG, Beijing (CN)

(73) Assignee: BOE Technology Group Co., Ltd., Beijing (CN)

(21) Appl. No.: 18/867,045

(22) PCT Filed: Nov. 8, 2023
(86) PCT No.: PCT/CN2023/130508

§ 371 Date: Nov. 19, 2024

(30) Foreign Application Priority Data
Dec. 1, 2022 (CN) 202211533207.6

(51) Int. Cl. C09K 11/06; C09K 11/02; H10K 50/858; H10K 101/40

(52) U.S. Cl. CPC C09K 11/06; C09K 11/02; H10K 50/858; C09K 2211/1007; C09K 2211/1011; C09K 2211/1014; C09K 2211/1022; H10K 2101/40

(57) ABSTRACT

An organic light-emitting device and a display apparatus. The organic light-emitting device includes a first electrode layer, a light-emitting functional layer, a second electrode layer, and a capping layer which are sequentially stacked; the capping layer includes a first capping layer material and a second capping layer material; and the first capping layer material and the second capping layer material satisfy: n₁(λ₁)−n₂(λ₁)≥0.2, 440 nm≤λ₁≤480 nm; n₁(λ₂)−n₂(λ₂)≥0.1, 500 nm≤λ₂≤550 nm; n₁(λ₃)−n₂(λ₃)≥0.1, 600 nm≤λ₃≤640 nm, wherein λ₁, λ₂, and λ₃ respectively represent different wavelength ranges of light, n1 represents the refractive index of the first capping layer material, and n2 represents the refractive index of the second capping layer material.

### CROSS-REFERENCE TO RELATED APPLICATIONS

The present disclosure is a U.S. National Stage Application of International Application No. PCT/CN2023/130508, filed on Nov. 8, 2023, which is based upon and claims priority to Chinese patent application No. 202211533207.6, filed Dec. 1, 2022, entitled “Organic Light-emitting device and display apparatus”, the entire contents of each are incorporated herein by reference.

### TECHNICAL FIELD

The present disclosure relates to the field of display technology, and in particular to an organic light-emitting device and a display apparatus.

### BACKGROUND

Organic light-emitting diode (OLED) devices currently used mostly use top-emitting device structures, using reflective anode and transparent cathode to enhance light extraction efficiency through microcavity effect. In this device, a very important functional layer is a capping layer (CPL). The capping layer includes two layers, the first layer is a high refractive index material, and the second layer is a low refractive index material. The capping layer achieves better light extraction effect through the combination of high and low refractive index.

However, the light-emitting effect of the existing capping layer material cannot meet the requirement of the user.

The above information disclosed in the background art part is only used to enhance understanding of the background of the present disclosure, and therefore it may include information that does not constitute the prior art known to those of ordinary skill in the art.

### SUMMARY OF THE INVENTION

The purpose of the present disclosure is to provide an organic light-emitting device and a display apparatus to improve the light-emitting efficiency of the device.

In order to achieve the above-mentioned invention object, the present disclosure adopts the following technical solutions:

According to a first aspect of the present disclosure, an organic light-emitting device is provided, including a first electrode layer, a light-emitting functional layer, a second electrode layer and a capping layer sequentially stacked, wherein the capping layer includes a first capping layer material and a second capping layer material;
the first capping layer material and the second capping layer material satisfy:

$${n}_{1} ( {λ}_{1} ) - {n}_{2} ( {λ}_{1} ) \geq 0.2 , 440 nm \leq {λ}_{1} \leq 480 nm ;$$

$${n}_{1} ( {λ}_{2} ) - {n}_{2} ( {λ}_{2} ) \geq 0.1 , 500 nm \leq {λ}_{2} \leq 550 nm ;$$

$${n}_{1} ( {λ}_{3} ) - {n}_{2} ( {λ}_{3} ) \geq 0.1 , 600 nm \leq {λ}_{3} \leq 640 nm ;$$

the light-emitting functional layer includes a hole transport layer, an organic light-emitting layer and an electron transport layer sequentially stacked in a direction away from the first electrode layer, and the hole transport layer, the organic light-emitting layer and the electron transport layer satisfy:

$$0.1 \leq {n}_{3} ( {λ}_{1} ) - {n}_{4} ( {λ}_{1} ) \leq 0.8 ; 0.1 \leq {n}_{3} ( {λ}_{2} ) - {n}_{4} ( {λ}_{2} ) \leq 0.8 ;$$

$$0.1 \leq {n}_{3} ( {λ}_{3} ) - {n}_{4} ( {λ}_{3} ) \leq 0.8 ;$$

$$0.1 \leq {n}_{5} ( {λ}_{1} ) - {n}_{4} ( {λ}_{1} ) \leq 0.8 ; 0.1 \leq {n}_{5} ( {λ}_{2} ) - {n}_{4} ( {λ}_{2} ) \leq 0.8 ;$$

$$0.1 \leq {n}_{5} ( {λ}_{3} ) - {n}_{4} ( {λ}_{3} ) \leq 0.8 ;$$

wherein, λ₁, λ₂, and λ₃ represent different wavelength ranges of light respectively;
n₁ represents the refractive index of the first capping layer material, and n₂ represents the refractive index of the second capping layer material;
n₃ represents the refractive index of the hole transport layer, n₄ represents the refractive index of the organic light emitting layer, and n₅ represents the refractive index of the electron transport layer.

In one exemplary embodiment of the present disclosure, the first capping layer material and the second capping layer material satisfy:

$${k}_{1} ( {λ}_{4} ) - {k}_{2} ( {λ}_{5} ) \geq 0.1 , {λ}_{4} = 405 nm , {λ}_{5} = 430 nm ;$$

$$0.8 \leq [ {k}_{2} ( {λ}_{4} ) - {k}_{2} ( {λ}_{5} ) ] / [ {k}_{1} ( {λ}_{4} ) - {k}_{1} ( {λ}_{5} ) ] \leq 1 ;$$

$${k}_{1} ( {λ}_{6} ) \leq 0.08 ; {k}_{2} ( {λ}_{6} ) \leq 0.08 , {λ}_{6} \geq 430 nm ;$$

wherein, λ₄, λ₅, and λ₆ represent different wavelength ranges of light respectively;
k₁ represents the absorption coefficient of the first capping layer material, and k₂ represents the absorption coefficient of the second capping layer material.

In an exemplary embodiment of the present disclosure, the first capping layer material is selected from a structure shown in Chemical Formula 1,

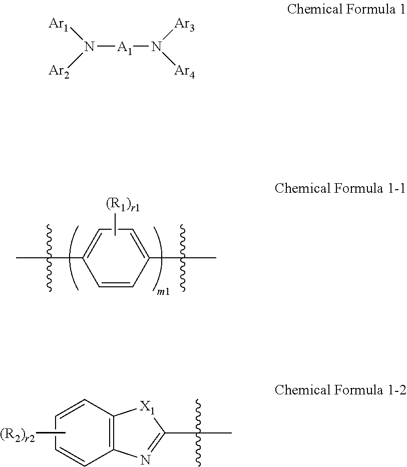

Wherein,

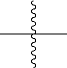

represents a chemical bond;
the group A₁ is selected from the structure represented by the Chemical Formula 1-1;
at least one of Ar₁, Ar₂, Ar₃ and Ar₄ is selected from the structure represented by Chemical Formula 1-2, when Ar₁, Ar₂, Ar₃ and Ar₄ are not selected from the structure represented by Chemical Formula 1-2, Ar₁, Ar₂, Ar₃ and Ar₄ are each independently selected from hydrogen, deuterium, halogen, alkyl with 1-6 carbon atoms, substituted or unsubstituted aryl with 6-20 carbon atoms, substituted or unsubstituted heteroaryl with 5-30 carbon atoms;
X₁ is selected from O or S;
R₁ is selected from hydroxyl, alkyl with 1-4 carbon atoms and aryl with 6-12 carbon atoms;
R₂ is selected from alkyl with 1-4 carbon atoms and aryl with 6-12 carbon atoms;
r1 is the number of R₁, and r1 is selected from 0, 1, 2, 3 or 4;
r2 is the number of R₂, and r2 is selected from 0, 1, 2, 3 or 4;
m1 is selected from 1, 2 or 3, and when m1 is more than 1, two adjacent benzene rings can be connected to form a ring;
the substituents on Ar₁, Ar₂, Ar₃, and Ar₄ are each independently selected from deuterium, halogen, alkyl with 1-4 carbon atoms, aryl with 6-12 carbon atoms, heteroaryl with 5-12 carbon atoms.

In one exemplary embodiment of the present disclosure, the group M is selected from the group consisting of:

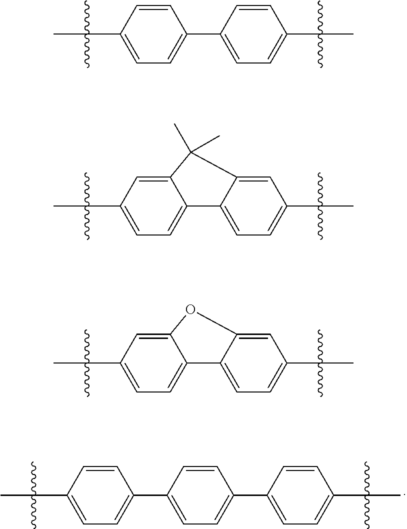 [SMILES: *c1ccc(-c2ccc(*)cc2)cc1 ; *c1ccc2c(c1)C(C)(C)c1cc(*)ccc1-2 ; *c1ccc2c(c1)oc1cc(*)ccc12 ; *c1ccc(-c2ccc(-c3ccc(*)cc3)cc2)cc1]

In one exemplary embodiment of the present disclosure, Ar₁, Ar₂, Ar₃, and Ar₄ are each independently selected from the group consisting of hydrogen, substituted or unsubstituted phenyl, substituted or unsubstituted biphenyl, substituted or unsubstituted dibenzofuranyl, substituted or unsubstituted fluorenyl, and a structure represented by Chemical Formula 1-2;
the substituents on Ar₁, Ar₂, Ar₃ and Ar₄ are independently selected from deuterium, halogen, methyl, phenyl and pyridyl.

In an exemplary embodiment of the present disclosure, the second capping layer material is selected from an inorganic material or a structure represented by Chemical Formula 2,

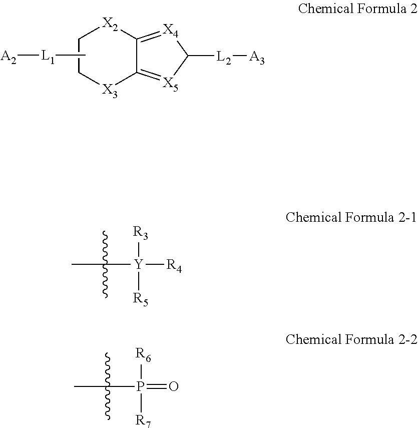

wherein,

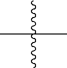

represents a chemical bond;
A₂ and A₃ are each independently selected from a structure represented by Chemical Formula 2-1 or Chemical Formula 2-2;
X₂ and X₃ are each independently selected from B(R₈), C(R₉R₁₀), O and S;
X₄ and X₅ are each independently selected from CH and N;
Y is selected from C and Si;
L₁ and L₂ are independently selected from substituted or unsubstituted arylidene with 6-20 carbon atoms;
R₃, R₄, R₅, R₆, R₇ are each independently selected from substituted or unsubstituted aryl having 6-20 carbon atoms;
R₈, R₉, R₁₀ are each independently selected from hydrogen, alkyl with 1-6 carbon atoms, substituted or unsubstituted aryl with 6-20 carbon atoms;
the substituents on L₁, L₂, R₃, R₄, R₅, R₆, R₇, R₈, R₉ and R₁₀ are independently selected from deuterium, halogen and alkyl with 1-6 carbon atoms;
the structure represented by Chemical Formula 2-1 or Chemical Formula 2-2 contains tert-butyl.

In one exemplary embodiment of the present disclosure, L₁, L₂ are each independently selected from substituted or unsubstituted phenylene groups.

In an exemplary embodiment of the present disclosure, wherein R₃, R₄, R₅, R₆, R₇ are each independently selected from substituted or unsubstituted phenyl;
the substituents on R₃, R₄, R₅, R₆ and R₇ are independently selected from methyl, ethyl and tert-butyl.

In an exemplary embodiment of the present disclosure, the light-emitting functional layer further includes an electron blocking layer and a hole blocking layer, the electron blocking layer is disposed between the hole transport layer and the organic light-emitting layer, and the hole blocking layer is disposed between the organic light-emitting layer and the electron transport layer;
the hole blocking layer and the electron transport layer satisfy:

$$0.4 eV \leq LUMO ( HBL ) - LUMO ( ETL ) \leq 1 eV ;$$

the electron blocking layer and the hole transport layer satisfy:

$$0.3 eV \leq HOMO ( HTL ) - HOMO ( EBL ) \leq 1 eV ;$$

wherein LUMO (HBL) is the lowest unoccupied molecular orbital LUMO energy level of the hole blocking layer material, and LUMO (ETL) is the lowest unoccupied molecular orbital LUMO energy level of the electron transport layer material;
HOMO (HTL) is the highest occupied molecular orbital HOMO energy level of the hole transport layer material, and HOMO (EBL) is the highest occupied molecular orbital HOMO energy level of the electron blocking layer material.

In one exemplary embodiment of the present disclosure, the organic light-emitting layer material includes a host material and a dopant material;
the host material of the organic light-emitting layer and the hole blocking layer satisfy:

$$T 1 ( HBL ) > T 1 ( Host ) ;$$

the host material of the organic light-emitting layer and the electron blocking layer satisfy:

$$T 1 ( EBL ) > T 1 ( Host ) ;$$

wherein T1(HBL) is the lowest triplet energy of the hole blocking layer material, T1 (EBL) is the lowest triplet energy of the electron blocking layer material, and T1(Host) is the lowest triplet energy of the organic light-emitting layer host material.

In one exemplary embodiment of the present disclosure, the host material of the organic light-emitting layer and the doping material of the organic light-emitting layer satisfy:

$$T 1 ( Dopant ) > T 1 ( Host ) ;$$

$$S 1 ( Host ) > S 1 ( Dopant ) ;$$

wherein T1(Dopant) is the lowest triplet excitation energy of the doped material of the organic light-emitting layer, S1(Host) is the lowest singlet excitation energy of the host material of the organic light-emitting layer, S1(Dopant) is the lowest singlet excitation energy of the doping material of the organic light-emitting layer.

In an exemplary embodiment of the present disclosure, the hole mobility and the electron mobility of the organic light-emitting layer satisfy:

$$0.01 < μ h ( EML ) / μ e ( EML ) \leq 100 ;$$

wherein, μh(EML) is the hole mobility of the organic light-emitting layer, and μe(EML) is the electron mobility of the organic light-emitting layer.

In an exemplary embodiment of the present disclosure, the light-emitting functional layer further includes a hole injection layer disposed between the first electrode layer and the hole transport layer;

the resistivity of the hole injection layer is not less than 100 Ω·m.

In an exemplary embodiment of the present disclosure, the capping layer includes a first capping layer and a second capping layer stacked in a direction away from the first electrode layer, the first capping layer includes the first capping layer material, and the second capping layer includes the second capping layer material;

wherein the molecular orientation of the first capping layer is between −0.5 and −0.2.

In one exemplary embodiment of the present disclosure, the inorganic material is selected from one or more of metal compounds, non-metal compounds, metals, and metal alloys.

According to a second aspect of the present disclosure, there is provided a display apparatus including an organic light-emitting device as described in the first aspect.

The organic light-emitting device provided by the present disclosure has a first covering layer material with a high refractive index and a second covering layer material with a low refractive index. The refractive indices of the first covering layer material and the second covering layer material satisfy different difference relationships in different wavelength ranges. Such difference relationships help to improve the light coupling efficiency of the organic light-emitting device, improve the light extraction mode, and achieve higher light extraction efficiency. In addition, by adjusting the refractive index relationship of the hole transport layer, the organic light-emitting layer, and the electron transport layer, the light extraction efficiency of the device is further improved.

### BRIEF DESCRIPTION OF THE DRAWINGS

The above and other features and advantages of the present disclosure will become more apparent by describing exemplary embodiments thereof in detail with reference to the accompanying drawings.

FIG. 1 is a schematic structural diagram of an organic light-emitting in an exemplary embodiment of the present disclosure.

FIG. 2 is a schematic structural diagram of an organic light-emitting in another exemplary embodiment of the present disclosure.

The main elements in the drawings are as follows:
100, first electrode layer; 200, second electrode layer; 300, light-emitting functional layer; 310, hole injection layer; 321, hole transport layer; 322, electron blocking layer; 330, organic light-emitting layer; 340, hole blocking layer; 350, electron transport layer; 360, electron injection layer; 400, capping layer.

### DETAILED DESCRIPTION

Example embodiments will now be described more fully with reference to the accompanying drawings. However, the example embodiments can be implemented in various forms, and should not be construed as being limited to the embodiments set forth herein. On the contrary, these embodiments are provided so that the present disclosure will be comprehensive and complete, and fully convey the concept of the example embodiments to those skilled in the art. The described features, structures, or characteristics can be combined in one or more embodiments in any suitable manner. In the following description, many specific details are provided to provide a full understanding of the disclosed embodiments.

In the figure, the thickness of the region and layer may have been exaggerated for clarity. The same reference numerals in the figure represent the same or similar structures, therefore their detailed descriptions will be omitted.

The described features, structures, or characteristics can be combined in one or more embodiments in any suitable manner. In the following description, many specific details are provided to provide a full understanding of the embodiments of the present disclosure. However, those skilled in the art will be mean that the disclosed technical solution can be practiced without one or more of the specific details described, or other methods, components, materials, and the like may be employed. In other cases, the well-known structures, materials, or operations are not shown or described in detail to avoid blurring the main technical ideas disclosed in the present disclosure.

When a certain structure is “on” other structures, it may refer to a structure being formed as a whole on other structures, or a structure being “directly” disposed on other structures, or a structure being “indirectly” disposed on other structures through another structure.

The terms “a”, “one”, “the” are used to indicate the existence of one or more elements/components/and the like. The terms “including” and “comprising” are used to indicate open inclusion and refer to the existence of additional elements/components/and the like in addition to the listed ones. The terms “first” and “second” are only used as markers and do not limit the number of their objects.

An organic Light-emitting device (OLED) is an active light-emitting device, which has advantages of light-emitting, ultra-thin, wide viewing angle, high brightness, high contrast, low power consumption, extremely high response speed and so on, and gradually becomes the next generation display technology with great development prospect. An OLED includes an anode, a cathode and an organic light-emitting layer arranged between the anode and the cathode. Its light-emitting principle is that holes and electrons are injected into the light-emitting layer from the anode and the cathode respectively. When the electrons and holes meet in the light-emitting layer, the electrons and holes recombine to generate excitons, and these excitons emit light while changing from an excited state to a ground state.

The OLED device can be divided into a bottom-emitting OLED device and a top-emitting OLED device according to the different light-emitting directions. In the bottom-emitting device, the light is emitted from the substrate, the reflective electrode is above the organic light-emitting layer, and the transparent electrode is below the organic light-emitting layer. The thin film transistor part in the bottom-emitting OLED device cannot transmit the light, resulting in a smaller light-emitting area. In top-emitting devices, the transparent electrode is on the organic light-emitting layer and the reflective electrode is below the organic light-emitting layer, so the light is emitted from the opposite direction of the substrate, thereby increasing the light transmission area. Therefore, the current OLED devices are mainly top-emitting devices.

The structure of the top-emitting device adopts the reflective anode and the transparent cathode to enhance the light extraction efficiency through the microcavity effect. In the device, the capping layer is set on the upper layer of the cathode to form the collocation with high and low refractive index so as to realize better light-emitting effect. However, in the related technology, the refractive index of the capping layer in the visible light range is low, resulting in low light extraction efficiency, the effect on improving the light-emitting efficiency of the OLED device is limited, and the light-emitting performance of the OLED device cannot satisfy the user requirement. The capping layer absorbs less ultraviolet light to the external environment, so it is difficult to avoid the device from being damaged by the ultraviolet light to the internal device, so that the service life of the OLED device is low, and the user experience is influenced.

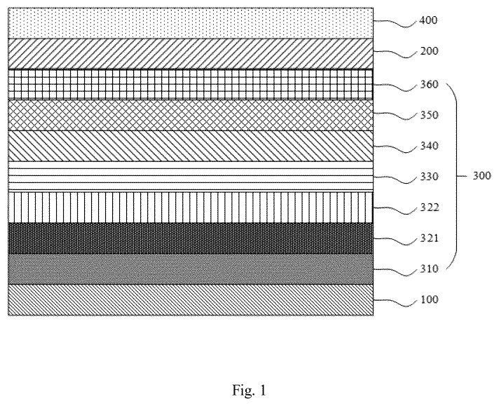

As shown in FIG. 1, the present disclosure provides an organic light-emitting device, which includes a first electrode layer 100, a light-emitting functional layer 300, a second electrode layer 200 and a capping layer 400 sequentially stacked, wherein the capping layer 400 includes a first capping layer material and a second capping layer material. The first capping layer material and the second capping layer material satisfy:

$${n}_{1} ( {λ}_{1} ) - {n}_{2} ( {λ}_{1} ) \geq 0.2 , 440 nm \leq {λ}_{1} \leq 480 nm ;$$

$${n}_{1} ( {λ}_{2} ) - {n}_{2} ( {λ}_{2} ) \geq 0.1 , 500 nm \leq {λ}_{2} \leq 550 nm ;$$

$${n}_{1} ( {λ}_{3} ) - {n}_{2} ( {λ}_{3} ) \geq 0.1 , 600 nm \leq {λ}_{3} \leq 640 nm ;$$

The light-emitting functional layer 300 includes a hole transport layer 321, an organic light-emitting layer 330 and an electron transport layer 350 sequentially stacked along a direction away from the first electrode layer 100. The hole transport layer 321, the organic light-emitting layer 330 and the electron transport layer 350 satisfy:

$$0.1 \leq {n}_{3} ( {λ}_{1} ) - {n}_{4} ( {λ}_{1} ) \leq 0.8 ; 0.1 \leq {n}_{3} ( {λ}_{2} ) - {n}_{4} ( {λ}_{2} ) \leq 0.8 ;$$

$$0.1 \leq {n}_{3} ( {λ}_{3} ) - {n}_{4} ( {λ}_{3} ) \leq 0.8 ;$$

$$0.1 \leq {n}_{5} ( {λ}_{1} ) - {n}_{4} ( {λ}_{1} ) \leq 0.8 ; 0.1 \leq {n}_{5} ( {λ}_{2} ) - {n}_{4} ( {λ}_{2} ) \leq 0.8 ;$$

$$0.1 \leq {n}_{5} ( {λ}_{3} ) - {n}_{4} ( {λ}_{3} ) \leq 0.8 ;$$

wherein, λ₁, λ₂, and λ₃ represent different wavelength ranges of light respectively;
n₁ represents the refractive index of the first capping layer material, and n₂ represents the refractive index of the second capping layer material;
n₃ represents the refractive index of the hole transport layer 321, n₄ represents the refractive index of the organic light emitting layer 330, and n₅ represents the refractive index of the electron transport layer 350.

The organic light-emitting device provided by the present disclosure has a first covering layer material with a high refractive index and a second covering layer material with a low refractive index. The refractive indices of the first covering layer material and the second covering layer material satisfy different difference relationships in different wavelength ranges. Such difference relationships help to improve the light coupling efficiency of the organic light-emitting device, improve the light extraction mode, and achieve higher light extraction efficiency. In addition, by adjusting the refractive index relationship of the hole transport layer 321, the organic light-emitting layer 330, and the electron transport layer 350, the light extraction efficiency of the device is further improved.

The components of the organic light-emitting device provided in the embodiments of the present disclosure will be described in detail below with reference to the accompanying drawings.

The organic light-emitting device provided by the present disclosure includes a first electrode layer 100, a light-emitting functional layer 300, a second electrode layer 200, and a capping layer 400 sequentially stacked.

The first electrode layer 100 may be used as an anode of a light-emitting device. Optionally, the anode includes the following anode material, which are preferably materials with a large work function that facilitate hole injection into the functional layer. Specific examples of the anode material include: metals such as nickel, platinum, vanadium, chromium, copper, zinc and gold or their alloys; metal oxides such as zinc oxide, indium oxide, indium tin oxide (ITO) and indium zinc oxide (IZO); combined metals and oxides such as ZnO:Al or SnO₂:Sb; or a conductive polymers such as poly(3-methylthiophene), poly[3,4-(ethylene-1,2-dioxy) thiophene] (PEDT), polypyrrole and polyaniline, but not limited thereto. Preferably, a transparent electrode including indium tin oxide (indium tin oxide) (ITO) as an anode is included.

The second electrode layer 200 may be used as a cathode of a light-emitting device, and the cathode is preferably a material having a low work function so as to easily inject electrons into the organic light-emitting layer 330, and having good light transmittance and conductivity. Specific examples of cathode materials that may be used in the present disclosure include: metals, metal oxides, metal alloys, such as aluminium (Al), silver (Ag), gold (Au), magnesium (Mg), calcium (Ca), ytterbium (Yb), indium (In), lithium (Li), potassium (K), sodium (Na), tin (Sn), titanium (Ti), lead (Pb), samarium (Sm), yttrium (Y), indium tin oxide (ITO), magnesium-silver alloy (Mg:Ag), ytterbium-gold alloy (Yb:Au), ytterbium-silver alloy (Yb:Ag), lithium-aluminium alloy (Li:Al), lithium-calcium-magnesium alloy (Li:Ca:Al) and so on; and laminate materials, such as magnesium/aluminum (Mg/Al), magnesium/silver (Mg/Ag), aluminum/silver (Al/Ag), aluminum/gold (Al/Au), ytterbium/gold (Yb/Au), ytterbium/silver (Yb/Ag), calcium/magnesium (Ca/Mg), calcium/silver (Ca/Ag), and the like, but not limited thereto.

The light-emitting functional layer 300 may include a hole transport layer 321, an organic light-emitting layer 330 and an electron-transport layer 350 which are sequentially stacked in a direction away from the first electrode layer 100. Holes are injected into the organic light-emitting layer 330 from the anode and the hole transport layer 321, and electrons are injected into the organic light-emitting layer 330 from the cathode and the electron transport layer 350. When electrons and holes meet in the organic light-emitting layer 330, the electrons and holes recombine in the organic light-emitting layer 330 to generate excitons, and these excitons emit light while changing from an excited state to a ground state.

The capping layer 400 is disposed on the side of the second electrode layer 200 away from the first electrode layer 100. The capping layer 400 includes a first capping layer material and a second capping layer material. It should be noted that the capping layer 400 may be formed by mixing the first capping layer material and the second capping layer material through a film formation process. The first capping layer may also be formed of the first capping layer material, and the second capping layer may be formed of the second capping layer material, the second capping layer being disposed on the side of the first capping layer away from the first electrode layer 100. The first capping layer material and the second capping layer material can improve the luminous efficiency of the device.

In the present disclosure, the first capping layer material and the second capping layer material satisfy:

$${n}_{1} ( {λ}_{1} ) - {n}_{2} ( {λ}_{1} ) \geq 0.2 , 440 nm \leq {λ}_{1} \leq 480 nm ;$$

$${n}_{1} ( {λ}_{2} ) - {n}_{2} ( {λ}_{2} ) \geq 0.1 , 500 nm \leq {λ}_{2} \leq 550 nm ;$$

$${n}_{1} ( {λ}_{3} ) - {n}_{2} ( {λ}_{3} ) \geq 0.1 , 600 nm \leq {λ}_{3} \leq 640 nm ;$$

wherein, λ₁, λ₂, and λ₃ represent different wavelength ranges of light respectively;
n₁ represents the refractive index of the first capping layer material, and n₂ represents the refractive index of the second capping layer material.

Wherein, the light in the wavelength range of 440 nm to 480 nm is blue light, the light in the wavelength range of 500 nm to 550 nm is green light, and the light in the wavelength range of 600 nm-640 nm is red light. When the refractive index of the first capping layer material and the second capping layer material satisfy the above relationship, the first capping layer material and the second capping layer material are matched with each other to help to improve the optical coupling efficiency of the device, improve the light-emitting mode, the light originally limited in the device can be emitted out of the device, which shows higher light extraction efficiency.

Specifically, n₁(λ₁)−n₂(λ₁)≥0.2, 0.25, 0.3, 0.32, 0.35, 0.4, 0.45, 0.5, 0.6 or 0.7, but not limited thereto;
n₁(λ₂)−n₂(λ₂)≥0.1, 0.2, 0.25, 0.3, 0.32, 0.35, 0.4, 0.45, 0.5, 0.6 or 0.7, but not limited thereto;
n₁(λ₃)−n₂(λ₃)≥0.1, 0.2, 0.25, 0.3, 0.32, 0.35, 0.4, 0.45, 0.5, 0.6 or 0.7, but is not limited thereto.

$$Specifically , {n}_{1} ( {λ}_{1} = 460 ) - {n}_{2} ( {λ}_{1} = 460 ) \geq 0.2 ;$$

$${n}_{1} ( {λ}_{2} = 530 ) - {n}_{2} ( {λ}_{2} = 530 ) \geq 0.1 ;$$

$${n}_{1} ( {λ}_{3} = 620 ) - {n}_{2} ( {λ}_{3} = 620 ) \geq 0.1 .$$

Furthermore, the present disclosure further improves the light-emitting efficiency of the device by adjusting the refractive indices of the hole transport layer 321, the organic light-emitting layer 330 and the electron transport layer 350.

The hole transport layer 321, the organic light-emitting layer 330 and the electron transport layer 350 satisfy:

$$0.1 \leq {n}_{3} ( {λ}_{1} ) - {n}_{4} ( {λ}_{1} ) \leq 0.8 ; 0.1 \leq {n}_{3} ( {λ}_{2} ) - {n}_{4} ( {λ}_{2} ) \leq 0.8 ;$$

$$0.1 \leq {n}_{3} ( {λ}_{3} ) - {n}_{4} ( {λ}_{3} ) \leq 0.8 ;$$

$$0.1 \leq {n}_{5} ( {λ}_{1} ) - n 4 ( {λ}_{1} ) \leq 0.8 ; 0.1 \leq {n}_{5} ( {λ}_{2} ) - n 4 ( {λ}_{2} ) \leq 0.8 ;$$

$$0.1 \leq {n}_{5} ( {λ}_{3} ) - n 4 ( {λ}_{3} ) \leq 0.8 ;$$

wherein n₃ represents the refractive index of the hole transport layer 321, n₄ represents the refractive index of the organic light-emitting layer 330, and n₅ represents the refractive index of the electron transport layer 350.

$$Specifically , 0.1 \leq {n}_{3} ( {λ}_{1} = 460 ) - {n}_{4} ( {λ}_{1} = 460 ) \leq 0.8 ; \\ 0.1 \leq {n}_{3} ( {λ}_{2} = 530 ) - {n}_{4} ( {λ}_{2} = 530 ) \leq 0.8 ;$$

$$0.1 \leq {n}_{3} ( {λ}_{3} = 620 ) - {n}_{4} ( {λ}_{3} = 620 ) \leq 0.8 ;$$

$$0.1 \leq {n}_{5} ( {λ}_{1} = 460 ) - n 4 ( {λ}_{1} = 460 ) \leq 0.8 ; \\ 0.1 \leq {n}_{5} ( {λ}_{2} = 530 ) - n 4 ( {λ}_{2} = 530 ) \leq 0.8 ;$$

$$0.1 \leq {n}_{5} ( {λ}_{3} = 620 ) - n 4 ( {λ}_{3} = 620 ) \leq 0.8$$

It should be noted that, in the present disclosure, the numerical range of 0.1 to 0.8 may include 0.1, 0.2, 0.25, 0.3, 0.32, 0.35, 0.4, 0.45, 0.5, 0.6, 0.65, 0.7, 0.75 or 0.8, etc., but not limited thereto.

In some examples of the present disclosure, the first capping layer material and the second capping layer material further satisfy:

$${k}_{1} ( {λ}_{4} ) - {k}_{2} ( {λ}_{5} ) \geq 0.1 , {λ}_{4} = 405 nm , {λ}_{5} = 430 nm ;$$

$$0.8 \leq [ {k}_{2} ( {λ}_{4} ) - {k}_{2} ( {λ}_{5} ) ] / [ {k}_{1} ( {λ}_{4} ) - {k}_{1} ( {λ}_{5} ) ] \leq 1 ;$$

$${k}_{1} ( {λ}_{6} ) \leq 0.08 ; {k}_{2} ( {λ}_{6} ) \leq 0.08 , {λ}_{6} \geq 430 nm ;$$

wherein, λ₄, λ₅, and λ₆ represent different wavelength ranges of light respectively;
k₁ represents the absorption coefficient of the first capping layer material, and k₂ represents the absorption coefficient of the second capping layer material.

It should be noted that the numerical range of 0.8 to 1 in the present disclosure may include 0.8, 0.81, 0.82, 0.83, 0.84, 0.85, 0.86, 0.87, 0.88, 0.89, 0.9, 0.91, 0.92, 0.93, 0.94, 0.95, 0.96, 0.97, 0.98, 0.99 or 1.

Light with a wavelength of less than 430 nm is ultraviolet light. When k₁(λ₄)−k₂(λ₅)≥0.1, the first capping layer material and the second capping layer material can have better absorption in the wavelength range of 430 nm or less, so as to absorb the light harmful to the human body in the range to the maximum extent, and play a role in protecting the eyes. Further, when 0.8≤[k₂(λ₄)−k₂(λ₅)]/[k₁(λ₄)−k₁(λ₅)]≤1, in order to ensure that light less than 430 nm is well absorbed at the capping layer 400, light that is harmful to the human eye within the range is absorbed to a greater extent.

In addition, light with a wavelength greater than 430 nm is visible light and can be used for display. When k₁(λ₆)≤0.08 and k₂(λ₆)≤0.08, visible light can be prevented from being absorbed to ensure the light extraction efficiency of the device.

In some examples of the present disclosure, the first capping layer material is selected from the structure shown in Chemical Formula 1,

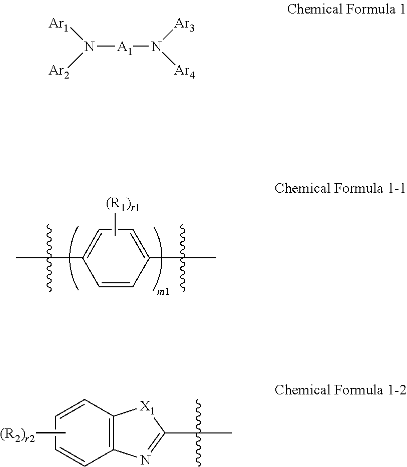

wherein,

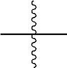

represents a chemical bond;
the group A₁ is selected from the structure represented by the Chemical Formula 1-1;
at least one of Ar₁, Ar₂, Ar₃ and Ar₄ is selected from the structure represented by Chemical Formula 1-2, when Ar₁, Ar₂, Ar₃ and Ar₄ are not selected from the structure represented by Chemical Formula 1-2, Ar₁, Ar₂, Ar₃ and Ar₄ are each independently selected from hydrogen, deuterium, halogen, alkyl with 1-6 carbon atoms, substituted or unsubstituted aryl with 6-20 carbon atoms, substituted or unsubstituted heteroaryl with 5-30 carbon atoms;
X₁ is selected from O or S;
R₁ is selected from hydroxyl, alkyl with 1-4 carbon atoms and aryl with 6-12 carbon atoms;
R₂ is selected from alkyl with 1-4 carbon atoms and aryl with 6-12 carbon atoms;
r1 is the number of R₁, and r1 is selected from 0, 1, 2, 3 or 4;
r2 is the number of R₂, and r2 is selected from 0, 1, 2, 3 or 4;
m1 is selected from 1, 2 or 3, and when m1 is more than 1, two adjacent benzene rings can be connected to form a ring;
the substituents on Ar₁, Ar₂, Ar₃, and Ar₄ are each independently selected from deuterium, halogen, alkyl with 1-4 carbon atoms, aryl with 6-12 carbon atoms, heteroaryl with 5-12 carbon atoms.

The second capping layer material is selected from inorganic material or the structure shown in Chemical Formula 2,

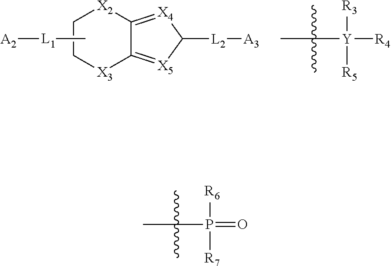

wherein,

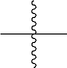

represents a chemical bond;
A₂ and A₃ are each independently selected from a structure represented by Chemical Formula 2-1 or Chemical Formula 2-2;
X₂ and X₃ are each independently selected from B(R₈), C(R₉R₁₀), O and S;
X₄ and X₅ are each independently selected from CH and N;
Y is selected from C and Si;
L₁ and L₂ are independently selected from substituted or unsubstituted arylidene with 6-20 carbon atoms;
R₃, R₄, R₅, R₆, R₇ are each independently selected from substituted or unsubstituted aryl having 6-20 carbon atoms;
R₈, R₉, R₁₀ are each independently selected from hydrogen, alkyl with 1-6 carbon atoms, substituted or unsubstituted aryl with 6-20 carbon atoms;
the substituents on L₁, L₂, R₃, R₄, R₅, R₆, R₇, R₈, R₉ and R₁₀ are independently selected from deuterium, halogen and alkyl with 1-6 carbon atoms;
the structure represented by Chemical Formula 2-1 or Chemical Formula 2-2 contains tert-butyl.

In the present disclosure, the description methods used “each . . . is independently” and “ . . . each independently selected from” can be interchanged and should be understood in a broad sense. They can mean that in different groups, the specific options expressed by the same symbols do not affect each other, or that in the same group, the specific options expressed by the same symbols do not affect each other.

In the present disclosure, the non-positional connecting bond refers to the single bond

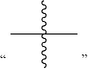

extending from a ring system, which means that one end of the connecting bond can be connected to any position in the ring system it passes, and the other end is connected to the rest of the compound molecule.

For example, as shown in the following formula (g), the benzoxazolyl represented by formula (g) is connected to other positions of the molecule through the non-positional connecting bond that passes the benzene ring and the oxazole ring, and its meaning includes any possible connection method shown in formulas (g-1) to (g-5).

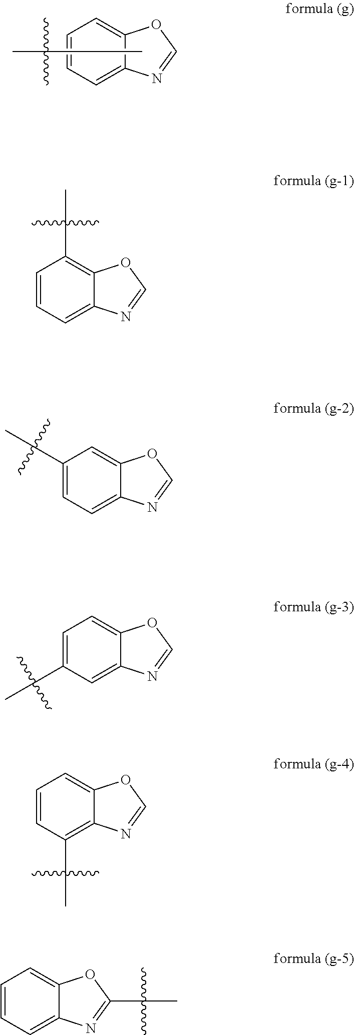

The non-positional substituent in the present disclosure refers to the substituent connected by a single bond extending from the center of the ring system, which means that the substituent may be connected to any possible position in the ring system. For example, in the following formula (h), the substituent R1 represented by the formula (h) is connected to the benzene ring through a non-positional connecting bond, and and its meaning includes any possible connection method shown in formulas (h-1) to the formula (h-4).

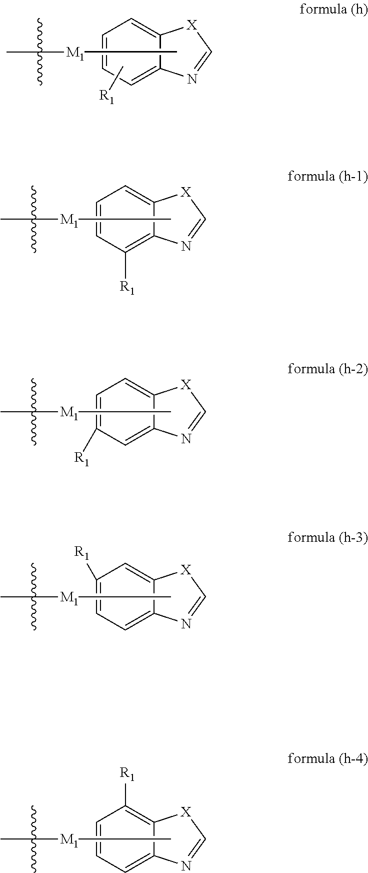

In the present disclosure, the number of carbon atoms of Ar₁, Ar₂, Ar₃, and Ar₄, L₁, L₂, Ar₁, R₁ to R₁₀ means the total number of carbon atoms. For example, if L₁ is selected from a substituted arylene group having 12 carbon atoms, the total carbon number of the arylene group and the substituents thereon is 12. For example, Ar₁ is

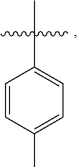 [SMILES: *c1ccc(C)cc1]

then its carbon number is 7; L is

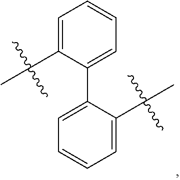 [SMILES: *c1ccccc1-c1ccccc1*]

then its carbon number is 12.

In the present disclosure, when no specific definition is otherwise provided, “hetero” means including at least one heteroatom such as N, O, S, etc. in a functional group and the remaining atoms are carbon and hydrogen. The unsubstituted alkyl may be a “saturated alkyl” without any double or triple bond.

In the present disclosure, “alkyl” may include straight-chain alkyl or branched-chain alkyl. Alkyl may have 1 to 10 carbon atoms, and in the present disclosure, a numerical range such as “1 to 10” refers to each integer in the given range. For example, “1 to 10 carbon atoms” refers to an alkyl that may contain 1 carbon atom, 2 carbon atoms, 3 carbon atoms, 4 carbon atoms, 5 carbon atoms, 6 carbon atoms, 7 carbon atoms, 8 carbon atoms, 9 carbon atoms, or 10 carbon atoms. Alkyl may also be a lower alkyl having 1 to 6 carbon atoms. In addition, the alkyl may be substituted or unsubstituted.

Optionally, the alkyl is selected from the group consisting of alkyls having 1 to 6 carbon atoms, and the specific examples include, but are not limited to, methyl, ethyl, n-propyl, isopropyl, n-butyl, isobutyl, sec-butyl, tert-butyl, pentyl, and hexyl.

In the present disclosure, “alkenyl” refers to a hydrocarbon group containing one or more double bonds in a linear or branched hydrocarbon chain. Alkenyl may be unsubstituted or substituted. The alkenyl may have 2 to 10 carbon atoms, such as, for example, 2 carbon atoms, 3 carbon atoms, 4 carbon atoms, 5 carbon atoms, 6 carbon atoms, 7 carbon atoms, 8 carbon atoms, 9 carbon atoms, 10 carbon atoms. For example, the alkenyl may be a vinyl group, a butadiene group, a propylene group, or the like.

In the present disclosure, cycloalkyl refers to a group derived from a saturated cyclic carbon chain structure. The cycloalkyl may have 3 to 10 carbon atoms, and in the present disclosure, a numerical range such as “3 to 10” refers to each integer in the given range. For example, “3 to 10 carbon atoms” refers to a cycloalkyl which may contain 3 carbon atoms, 4 carbon atoms, 5 carbon atoms, 6 carbon atoms, 7 carbon atoms, 8 carbon atoms, 9 carbon atoms, and 10 carbon atoms. The cycloalkyl may be substituted or unsubstituted.

Optionally, the specific examples of cycloalkyl include, but are not limited to, cyclopentyl, cyclohexyl and the like.

In the present disclosure, aryl refers to an optional functional group or substituent derived from an aromatic carbocycle. The aryl may be monocyclic aryl (e.g., phenyl) or polycyclic aryl, in other words, the aryl may be monocyclic aryl, polycyclic aryl, two or more monocyclic aryls conjugated via carbon-carbon bonds, monocyclic aryl and polycyclic aryl conjugated via carbon-carbon bond, two or more polycyclic aryls conjugated via carbon-carbon bonds. That is, unless otherwise indicated, two or more aromatic groups conjugated by carbon-carbon bonds may also be regarded as aryl of the present disclosure. The polycyclic aryls may include, for example, bicyclic fused aryls (e.g., naphthyl), tricyclic fused aryls (e.g., phenanthrenyl, fluorenyl, anthryl), and the like. The aryl does not contain hetero atoms such as B, N, O, S, P, Se and Si. For example, in the present disclosure, biphenylyl, terphenyl, and the like are aryls. Examples of aryls may include, but are not limited to, phenyl, naphthyl, fluorenyl, anthryl, phenanthrenyl, biphenyl, terphenyl, terphenyl, pentabiphenyl, benzo [9,10]phenanthrenyl, pyrenyl, benzofluoranthryl, chrysenyl, and the like. The “aryl” of the present disclosure may contain 6 to 30 carbon atoms, in some examples, the number of carbon atoms in the aryl may be 6 to 25, in other examples the number of carbon atoms in the aryl may be 6 to 18, and in other examples the number of carbon atoms in the aryl may be 6 to 13. For example, in the present disclosure, the number of carbon atoms in the aryl may be 6, 10, 12, 13, 14, 15, 18, 20, 24, 25 or 30, and of course, the number of carbon atoms may also be other numbers, which are not listed here one by one. In the present disclosure, biphenylyl may be understood as phenyl substituted aryl, and may also be understood as unsubstituted aryl.

In the present disclosure, arylene refers to a divalent group formed by the further loss of one hydrogen atom from the aryl.

In the present disclosure, the substituted aryl may be one or more than two hydrogen atoms in the aryl may be substituted with the group such as deuterium atom, halogen group, cyano, aryl, heteroaryl, alkyl, cycloalkyl, and the like. Specific examples of heteroaryl-substituted aryls include, but are not limited to, dibenzofuranyl-substituted phenyl, dibenzothiophene-substituted phenyl, pyridine-substituted phenyl, and the like. It should be understood that the number of carbon atoms of the substituted aryl refers to the total number of carbon atoms of the aryl and the substituent on the aryl, for example, a substituted aryl having 18 carbon atoms, refers to the total number of carbon atoms of the aryl and the substituent thereof.

In the present disclosure, specific examples of aryl as a substituent include, but are not limited to, phenyl, naphthyl, biphenyl and so on.

In the present disclosure, heteroaryl refers to a monovalent aromatic ring or derivative thereof containing at least one heteroatom in the ring, and the heteroatom may be at least one of O, N and S. The heteroaryl may be a monocyclic heteroaryl or a polycyclic heteroaryl, in other words, the heteroaryl may be a single aromatic ring system, or may be a plurality aromatic ring systems conjugated to each other via carbon-carbon bonds, and any aromatic ring system may be an aromatic monocyclic ring or an aromatic fused ring. Exemplary heteroaryls may include thienyl, furyl, pyrrolyl, imidazolyl, thiazolyl, oxazolyl, oxadiazolyl, triazolyl, pyridyl, bipyridyl, pyrimidinyl, triazinyl, acridinyl, pyridazinyl, pyrazinyl, quinolinyl, quinazolinyl, quinoxalinyl, phenoxazinyl, phthalazinyl, Pyridopyrimidinyl, pyridopyrazinyl, pyrazinopyrazinyl, isoquinolinyl, indolyl, carbazolyl, benzoxazolyl, benzimidazolyl, benzothiazolyl, benzotriazolyl, benzocarbazolyl, benzothienyl, dibenzothienyl, thiophenothienyl, benzofuranyl, phenanthrolinyl, isoxazolyl, Thiadiazolyl, benzothiazolyl, phenothiazinyl, silafluorenyl, dibenzofuranyl, and N-arylcarbazolyl (e.g., N-phenylcarbazolyl), N-heteroarylcarbazolyl (e.g., N-pyridylcarbazolyl), N-alkylcarbazolyl (e.g., N-methylcarbazolyl), and the like, and not limited thereto, wherein, thienyl, furyl, phenanthrolinyl and so on are heteroaryls of single aromatic ring system type, and N-arylcarbazolyl and N-heteroarylcarbazolyl are heteroaryls of plurality aromatic ring system type connected by carbon-carbon bond conjugation. The “heteroaryl” of the present disclosure may contain 5 to 30 carbon atoms, in some embodiments, the number of carbon atoms in the heteroaryl may be 5 to 23, and in other embodiments, the number of carbon atoms in the aryl may be 5 to 19. For example, the number of carbon atoms can be 5, 6, 7, 10, 11, 12, 13, 18, 19, 20, 21, 22, 23, 25 or 30. Of course, the number of carbon atoms can also be other numbers, which are not listed here.

In the present disclosure, heteroaryl involved refers to a divalent group formed by the further loss of one hydrogen atom from the heteroaryl.

In the present disclosure, the substituted heteroaryl may be one or more hydrogen atoms in the heteroaryl substituted with a group such as deuterium atom, halogen group, cyano, aryl, heteroaryl, alkyl, cycloalkyl, or the like. Specific examples of aryl-substituted heteroaryls include, but are not limited to, phenyl-substituted dibenzofuranyl, phenyl-substituted dibenzothienyl, N-phenylcarbazolyl, and the like. It should be understood that the number of carbon atoms of the substituted heteroaryl refers to the total number of carbon atoms of the substituents on the heteroaryl and the heteroaryl.

In the present disclosure, specific examples of heteroaryl as a substituent include, but are not limited to pyridyl, benzimidazolyl, benzothiazolyl, benzoxazolyl, benzopyridyl, benzotriazolyl and the like.

In the present disclosure, halogen may include fluorine, iodine, bromine, chlorine and the like.

According to formula

$$\frac{{n}^{2} - 1}{{n}^{2} + 2} = \frac{4}{3} π \frac{{P}_{λ}}{V} ,$$

n is the refractive index of the molecule, λ is the wavelength of the irradiation light, and P_{λ} is the polarizability of the molecule. In the present disclosure, the molecular structure of the second capping layer material contains the structure represented by Chemical Formula 1-2, which contains heteroatoms such as O or S, which can greatly increase the polarizability of the material molecules, thereby helping to improve the refractive index of the material molecules. In addition, the molecule of the second capping layer material contains the structure shown in Chemical Formula 1-1, which contains benzene ring, when a plurality of benzene rings are connected, the area is orderly arranged, the material molecule number contained in the same volume will increase, correspondingly, the volume occupied by single material molecule is reduced, and the refractive index of the corresponding material molecule is increased.

Also according to the formula

$$\frac{{n}^{2} - 1}{{n}^{2} + 2} = \frac{4}{3} π \frac{{P}_{λ}}{V} ,$$

in the present disclosure, the molecular structure of the second capping layer material contains a large steric hindrance group represented by the Chemical Formula 2-1 or the Chemical Formula 2-2, and the introduction of the group into the material molecule can greatly increase the volume of the material molecule, and therefore, it is beneficial to reduce the refractive index of the material molecule. At the same time, the intrinsic refractive index of the phosphorus oxygen group, saturated carbon group, and silicon group contained in Chemical Formula 2-1 or Chemical Formula 2-2 is relatively small, and they also contain tert-butyl groups, which can greatly increase the distance between material molecules. The number of material molecules contained in the same volume will decrease, and correspondingly, the volume occupied by a single material molecule will increase, which can further reduce the refractive index of material molecules. secondly, the phosphorus oxygen group, the saturated carbon group, and silicon group have good stereoproperty and the large volume, which can improve the thermal stability of the material molecule, so as to obtain the material molecule with low refractive index and the thermal stability satisfying the requirements. In addition, the molecular structure of the second capping layer material contains atoms such as S, O, B and so on, which greatly reduces the refractive index of the molecule by breaking the conjugation.

In the present disclosure, “when m1>1, two adjacent benzene rings may be linked to form a ring” means that when Chemical Formula 1-1 contains two or more benzene rings, the substituents on two adjacent benzene rings may be linked to each other to form a ring, such as forming a structure such as

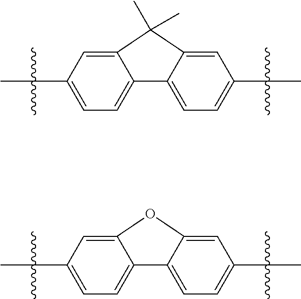 [SMILES: *c1ccc2c(c1)C(C)(C)c1cc(*)ccc1-2 ; *c1ccc2c(c1)oc1cc(*)ccc12]

and the like.

In some embodiments of the present disclosure, the group M is selected from the group consisting of:

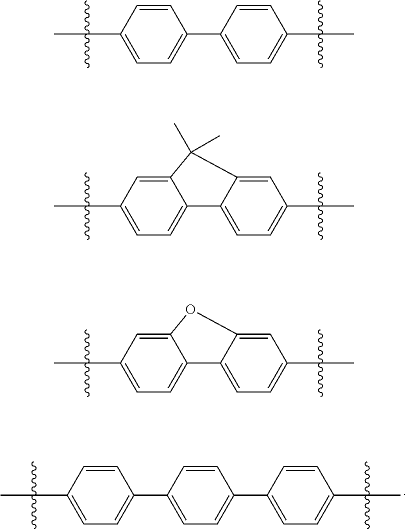 [SMILES: *c1ccc(-c2ccc(*)cc2)cc1 ; *c1ccc2c(c1)C(C)(C)c1cc(*)ccc1-2 ; *c1ccc2c(c1)oc1cc(*)ccc12 ; *c1ccc(-c2ccc(-c3ccc(*)cc3)cc2)cc1]

In some embodiments of the present disclosure, Ar₁, Ar₂, Ar₃ and Ar₄ are each independently selected from the group consisting of hydrogen, substituted or unsubstituted phenyl, substituted or unsubstituted biphenyl, substituted or unsubstituted dibenzofuranyl, substituted or unsubstituted fluorenyl, and the structure shown in Chemical Formula 1-2;
the substituents on Ar₁, Ar₂, Ar₃ and Ar₄ are independently selected from deuterium, halogen, methyl, phenyl and pyridyl.

Specifically, the second capping layer material is selected from the group consisting of the following structures:

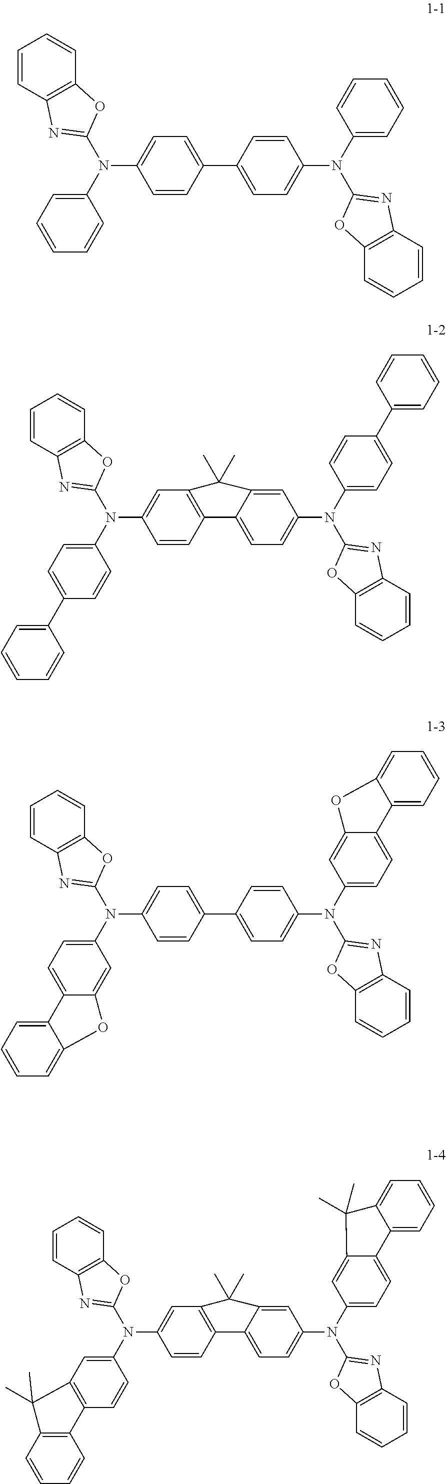 [SMILES: c1ccc(N(c2ccc(-c3ccc(N(c4ccccc4)c4nc5ccccc5o4)cc3)cc2)c2nc3ccccc3o2)cc1 ; CC1(C)c2cc(N(c3ccc(-c4ccccc4)cc3)c3nc4ccccc4o3)ccc2-c2ccc(N(c3ccc(-c4ccccc4)cc3)c3nc4ccccc4o3)cc21 ; c1ccc2oc(N(c3ccc(-c4ccc(N(c5ccc6c(c5)oc5ccccc56)c5nc6ccccc6o5)cc4)cc3)c3ccc4c(c3)oc3ccccc34)nc2c1 ; CC1(C)c2ccccc2-c2ccc(N(c3ccc4c(c3)C(C)(C)c3cc(N(c5ccc6c(c5)C(C)(C)c5ccccc5-6)c5nc6ccccc6o5)ccc3-4)c3nc4ccccc4o3)cc21]

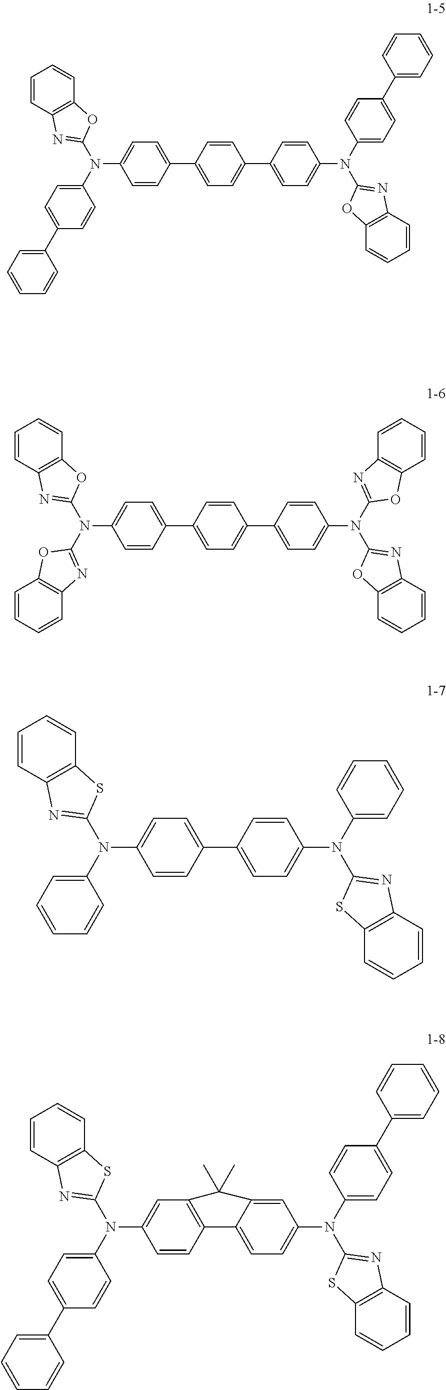 [SMILES: c1ccc(-c2ccc(N(c3ccc(-c4ccc(-c5ccc(N(c6ccc(-c7ccccc7)cc6)c6nc7ccccc7o6)cc5)cc4)cc3)c3nc4ccccc4o3)cc2)cc1 ; c1ccc2oc(N(c3ccc(-c4ccc(-c5ccc(N(c6nc7ccccc7o6)c6nc7ccccc7o6)cc5)cc4)cc3)c3nc4ccccc4o3)nc2c1 ; c1ccc(N(c2ccc(-c3ccc(N(c4ccccc4)c4nc5ccccc5s4)cc3)cc2)c2nc3ccccc3s2)cc1 ; CC1(C)c2cc(N(c3ccc(-c4ccccc4)cc3)c3nc4ccccc4s3)ccc2-c2ccc(N(c3ccc(-c4ccccc4)cc3)c3nc4ccccc4s3)cc21]

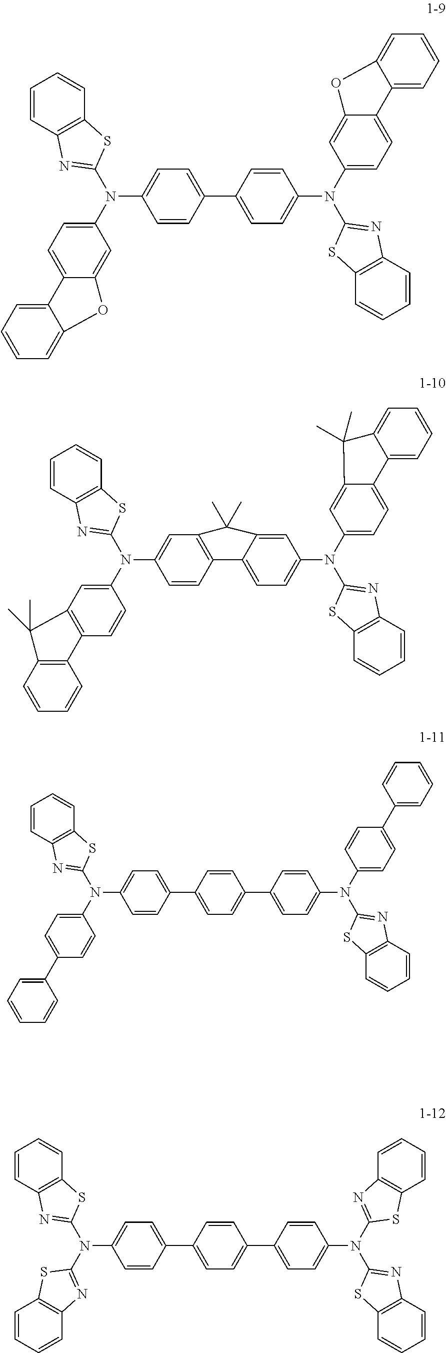 [SMILES: c1ccc2sc(N(c3ccc(-c4ccc(N(c5ccc6c(c5)oc5ccccc56)c5nc6ccccc6s5)cc4)cc3)c3ccc4c(c3)oc3ccccc34)nc2c1 ; CC1(C)c2ccccc2-c2ccc(N(c3ccc4c(c3)C(C)(C)c3cc(N(c5ccc6c(c5)C(C)(C)c5ccccc5-6)c5nc6ccccc6s5)ccc3-4)c3nc4ccccc4s3)cc21 ; c1ccc(-c2ccc(N(c3ccc(-c4ccc(-c5ccc(N(c6ccc(-c7ccccc7)cc6)c6nc7ccccc7s6)cc5)cc4)cc3)c3nc4ccccc4s3)cc2)cc1 ; c1ccc2sc(N(c3ccc(-c4ccc(-c5ccc(N(c6nc7ccccc7s6)c6nc7ccccc7s6)cc5)cc4)cc3)c3nc4ccccc4s3)nc2c1]

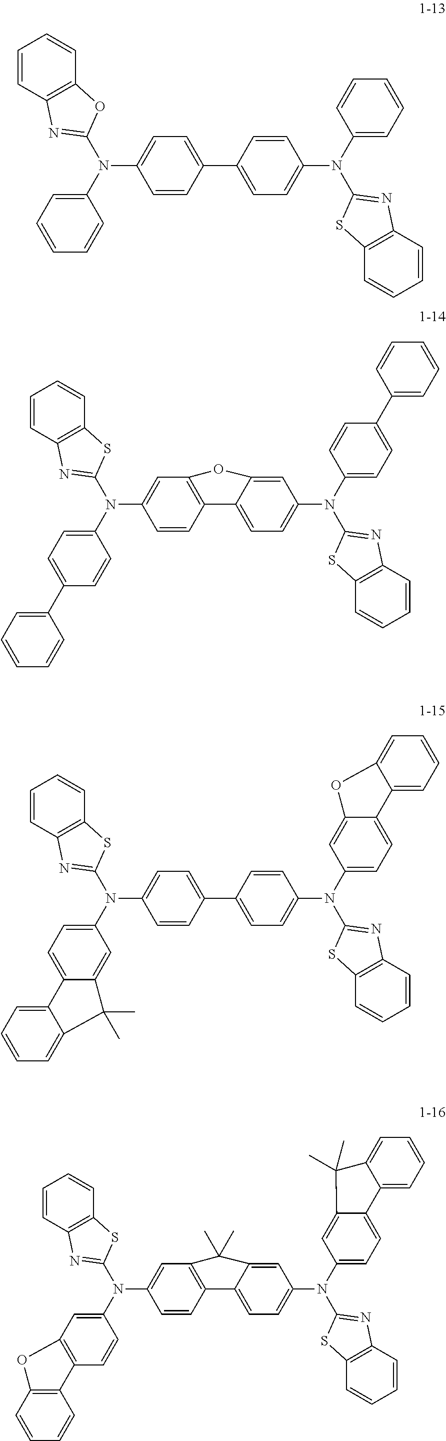 [SMILES: c1ccc(N(c2ccc(-c3ccc(N(c4ccccc4)c4nc5ccccc5s4)cc3)cc2)c2nc3ccccc3o2)cc1 ; c1ccc(-c2ccc(N(c3ccc4c(c3)oc3cc(N(c5ccc(-c6ccccc6)cc5)c5nc6ccccc6s5)ccc34)c3nc4ccccc4s3)cc2)cc1 ; CC1(C)c2ccccc2-c2ccc(N(c3ccc(-c4ccc(N(c5ccc6c(c5)oc5ccccc56)c5nc6ccccc6s5)cc4)cc3)c3nc4ccccc4s3)cc21 ; CC1(C)c2ccccc2-c2ccc(N(c3ccc4c(c3)C(C)(C)c3cc(N(c5ccc6c(c5)oc5ccccc56)c5nc6ccccc6s5)ccc3-4)c3nc4ccccc4s3)cc21]

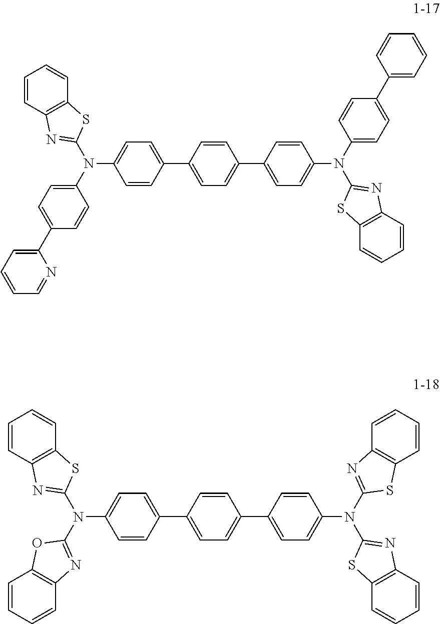 [SMILES: c1ccc(-c2ccc(N(c3ccc(-c4ccc(-c5ccc(N(c6ccc(-c7ccccn7)cc6)c6nc7ccccc7s6)cc5)cc4)cc3)c3nc4ccccc4s3)cc2)cc1 ; c1ccc2oc(N(c3ccc(-c4ccc(-c5ccc(N(c6nc7ccccc7s6)c6nc7ccccc7s6)cc5)cc4)cc3)c3nc4ccccc4s3)nc2c1]

In some embodiments of the present disclosure, L₁, L₂ are each independently selected from the group consisting of substituted or unsubstituted phenylene; R₃, R₄, R₅, R₆, R₇ are each independently selected from substituted or unsubstituted phenyl; the substituents on R₃, R₄, R₅, R₆ and R₇ are independently selected from methyl, ethyl and tert-butyl.

Specifically, the second capping layer material is selected from the group consisting of inorganic materials or the following structures:

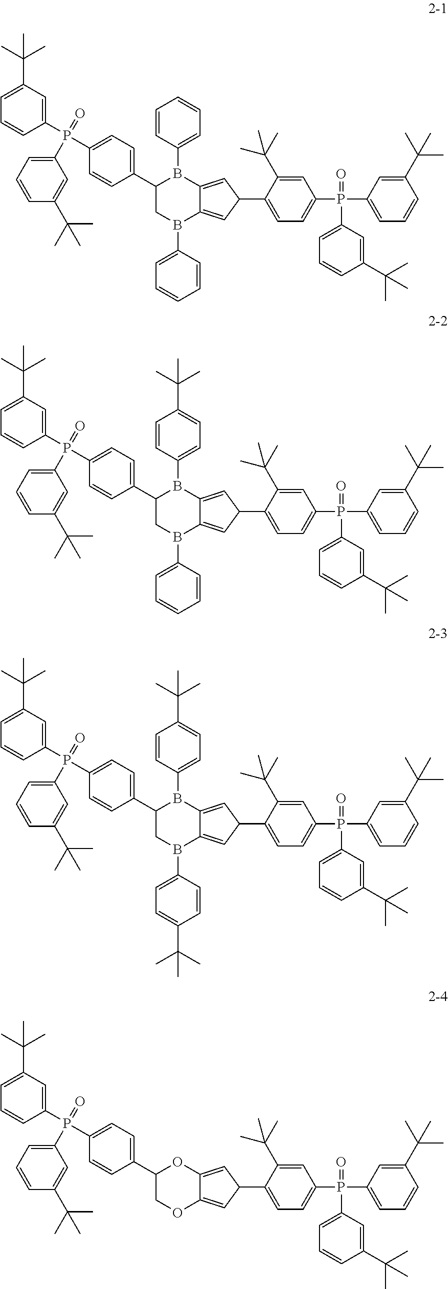

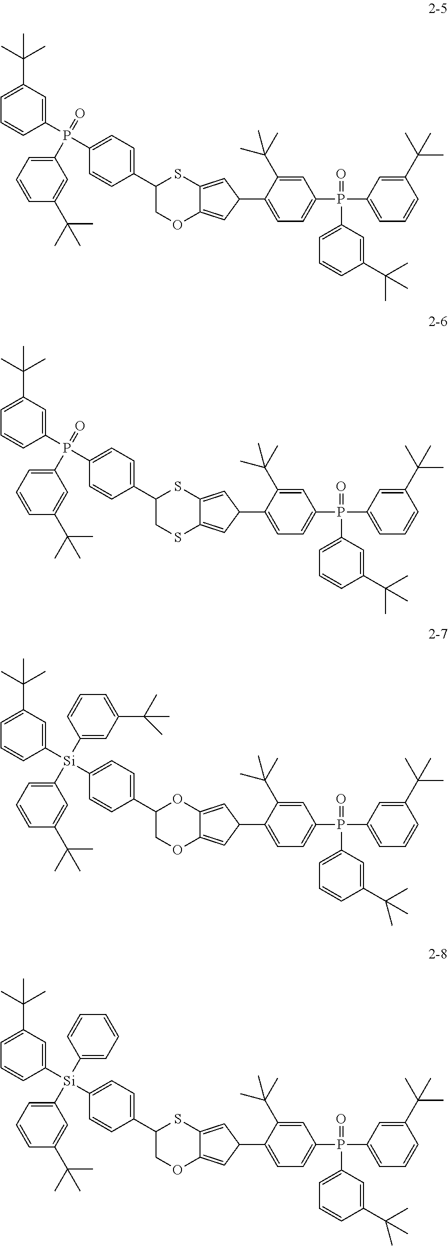

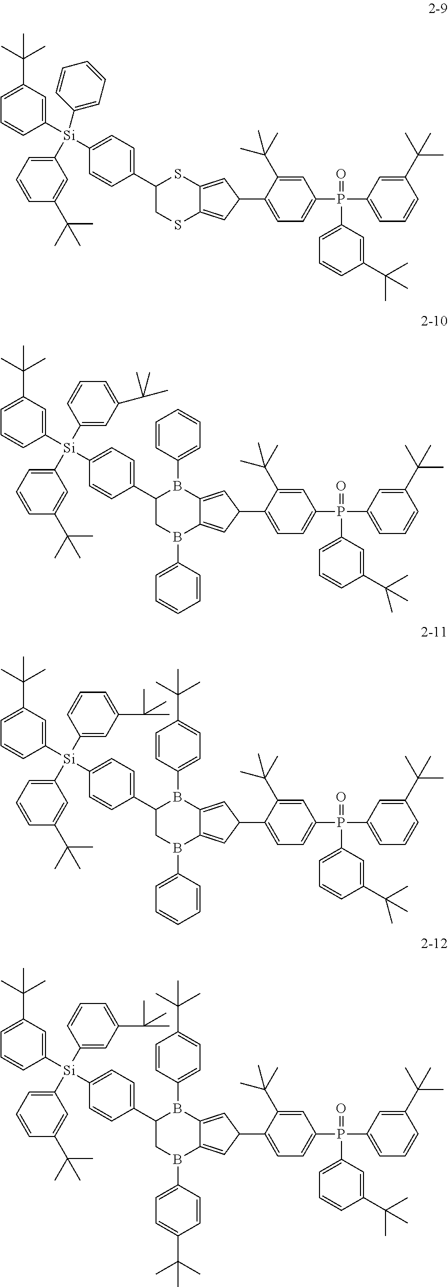

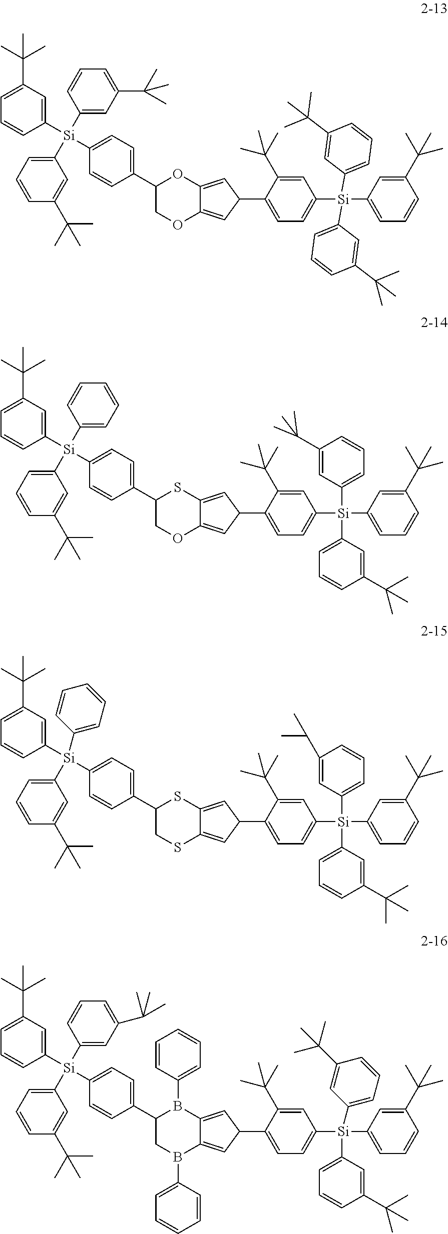

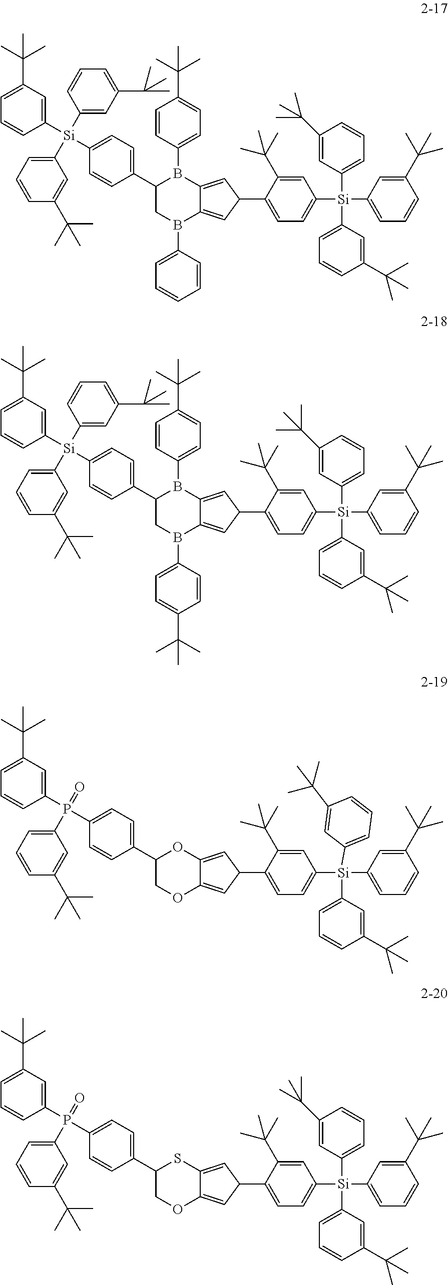

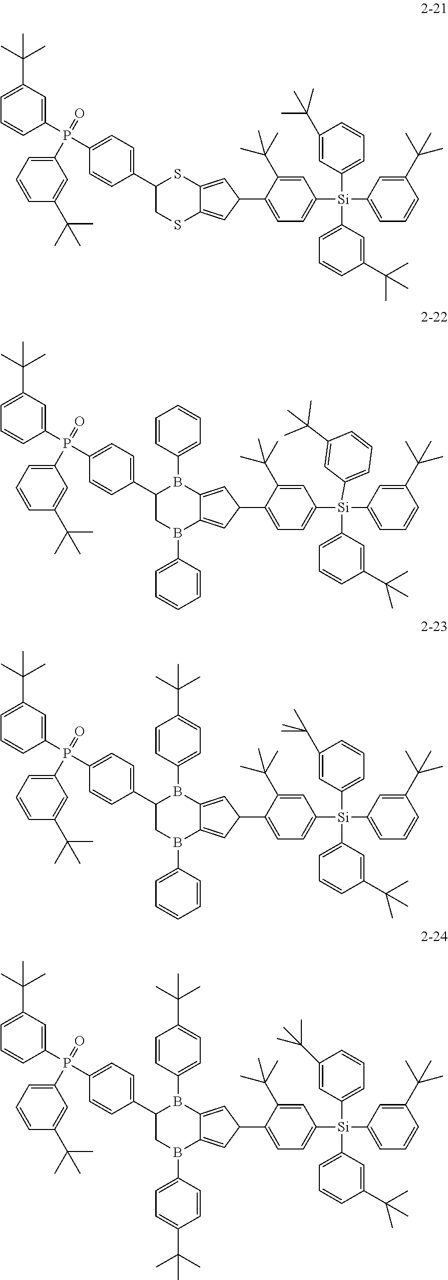

When the second capping layer material is an inorganic material, the inorganic material may be a metal compound, a non-metal compound, a metal or a metal alloy. The metal compound includes a metal oxide, a metal nitride, a metal oxynitride, a metal carbide, a metal salt, and the like. The non-metal compound includes non-metal oxides, non-metal nitrides, non-metal nitrogen oxides and so on. The metal includes alkali metals, alkaline-earth metals, transition metals, lanthanide metals, actinide metals and main group metals.

Specifically, the second capping layer material may be selected from but not limited to the following materials.

Examples of the metal compound include, but are not limited to, lithium fluoride (LiF), zinc oxide (ZnO), tin dioxide (SnO₂), magnesium oxide (MgO), vanadium pentoxide (V₂O₅), aluminum oxide (Al₂O₃), cadmium oxide (CdO), cobalt oxide (CoO), aluminium oxynitride (AlON), lithium boron oxide (LiBO₂), barium oxide (BaO), beryllium oxide (BeO), strontium oxide (SrO), indium tin oxide (ITO), calcium oxide (CaO), lithium fluoride (LiF), potassium bromide (KBr), magnesium fluoride (MgF₂), aluminium fluoride (AlF₃), calcium fluoride (CaF₂), cesium fluoride (CsF), sodium fluoride (NaF), potassium fluoride (KF), rubidium fluoride (RbF), strontium fluoride (SrF), ytterbium fluoride (YbF), yttrium fluoride (YF₃), barium (BaF₂), sodium iodide (NaI), potassium iodide (KI), rubidium iodide (RbI), cesium iodide (CsI), praseodymium fluoride (PrF₃), gadolinium fluoride (GdF₃), lanthanum fluoride (LaF₃), neodymium fluoride (NdF₃), barium fluoride (BaF₂), lithium chloride (LiCl), lithium bromide (LiBr), lithium iodide (LiI), sodium bromide (NaBr), rubidium bromide (RbBr), cesium bromide (CsBr), calcium chloride (CaCl₂)), zinc chloride (ZnCl), zinc bromide (ZnBr), stannous chloride (SnCl₂), silver chloride (AgCl), barium chloride (BaCl₂), magnesium chloride (MgCl₂), magnesium bromide (MgBr₂), magnesium iodide (MgI₂), silver bromide (AgBr), silver iodide (AgI), chromium fluoride (CrF₃), molybdenum dibromide (MoBr₂), bismuth trifluoride (BiF₃), lead fluoride (PbF₂), lead bromide (PbBr₂), strontium fluoride (SrF₂), cadmium fluoride (CdF₂), and the like.

In some embodiments of the present disclosure, the light-emitting functional layer 300 further includes an electron blocking layer 322 and an hole blocking layer 340, the electron blocking layer 322 is disposed between the hole transport layer 321 and the organic light-emitting layer 330, and the hole blocking layer 340 is disposed between the organic light-emitting layer 330 and the electron transport layer 350;

The hole blocking layer 340 and the hole transport layer 321 satisfy:

0.4 eV≤LUMO(HBL)−LUMO(ETL)≤1 eV. Wherein LUMO(HBL) is the lowest unoccupied molecular orbital LUMO energy level of the material of the electron blocking layer 322, and LUMO(ETL) is the lowest unoccupied molecular orbital LUMO energy level of the material of the electron transport layer 350. Within this range, the energy barrier between the electron blocking layer 322 and the electron transport layer 350 can be increased, and the electron transporting rate can be slowed down.

The electron blocking layer 322 and the hole transport layer 321 satisfy:

0.3 eV≤HOMO(HTL)−HOMO(EBL)≤1 eV. Wherein HOMO(HTL) is the highest occupied molecular orbital HOMO energy level of the material of the hole transport layer 321, and the HOMO(EBL) is the highest occupied molecular orbital HOMO energy level of the material of the electron blocking layer 322. Within this range, the cause of slow hole transport due to the energy level barrier can be eliminated.

In some embodiments of the present disclosure, the organic light-emitting layer 330 material includes a host material and a dopant material;
the host material of the organic light-emitting layer 330 and the electron blocking layer 322 satisfy:

$$T 1 ( HBL ) > T 1 ( Host ) ;$$

the host material of the organic light-emitting layer 330 and the electron blocking layer 322 satisfy:

$$T 1 ( EBL ) > T 1 ( Host ) ;$$

wherein, T1(HBL) is the lowest triplet energy of the material of the hole blocking layer 340, T1(EBL) is the lowest triplet energy of the material of the electron blocking layer 322, and T1 (Host) is the lowest triplet energy of the host material of the organic light-emitting layer 330. Within this range, the excitons are limited in the organic light-emitting layer 330 to ensure the light-emitting efficiency.

In some embodiments of the present disclosure, the host material of the organic light-emitting layer 330 and the doping material of the organic light-emitting layer 330 satisfy:

T1(Dopant)>T1(Host). Wherein, T1(Dopant) is the lowest triplet excitation energy of the doping material of the organic light-emitting layer 330. Within this range, singlet excitons are effectively generated on the host material by Triplet-triplet annihilation (TTA).

S1(Host)>S1(Dopant). S1 (Host) is the lowest singlet excitation energy of the host material of the organic light-emitting layer 330, and S1(Dopant) is the lowest singlet excitation energy of the doping material of the organic light-emitting layer 330. Within this range, the host material of the organic light-emitting layer 330 transfers excitons to the dopant material to generate fluorescence.

In some embodiments of the present disclosure, the hole mobility and the electron mobility of the organic light-emitting layer 330 satisfy:

0.01<μh(EML)/μe(EML)<100. Wherein, μh(EML) is the hole mobility of the organic light-emitting layer 330, and pe (EML) is the electron mobility of the organic light-emitting layer 330. Within this range, the composite region of the organic light-emitting layer 330 is not significantly offset to the interface difference of the electron blocking layer 322/organic light-emitting layer 330 or the electron blocking layer 322/organic light-emitting layer 330.

In some embodiments of the present disclosure, the light-emitting functional layer 300 further includes a hole injection layer 310 disposed between the first electrode layer 100 and the hole transport layer 321;

the resistivity of the hole injection layer 310 is not less than 100 Ω·m. The lateral current of the hole transport layer 321 in the adjacent organic light-emitting devices sharing the hole transport layer 321 is avoided, and after being used in a display panel, the color crosstalk problem between light-emitting devices is avoided.

Specifically, the hole injection layer 310 may be an inorganic oxide, a molybdenum oxide, a titanium oxide, a vanadium oxide, a rhenium oxide, a ruthenium oxide, a chromium oxide, a zirconium oxide, a hafnium oxide, a tantalum oxide, a silver oxide, a tungsten oxide, a manganese oxide, or the like. It can also be a dopant of a strong electron-withdrawing system, such as F4TCNQ (2,3,5,6-tetrafluoro-7,7′,8,8′-tetracyanodimethyl-p-benzoquinone), HATCN (2,3,6,7,10,11-hexacyano-1,4,5,8,9,12-hexaazatriphenylene) and the like. The p-type doping can also be performed on the hole-transporting material, and the hole-injecting layer 310 has a thickness of 5-20 nm, and the hole-injecting layer 310 is formed by co-evaporation.

The hole transport layer 321 has good hole transport characteristics and can be aromatic amine or carbazole materials such as NPB (N,N′-diphenyl-N,N′-(1-naphthyl)-1,1′-biphenyl-4,4′-diamine), TPD (N,N′-diphenyl-N,N′-di(3-methylphenyl)-1,1′-biphenyl-4,4′-diamine), DFLDPBi (4,4′-bis[N-(9,9-dimethylfluorene-2-yl)-N-phenylamine]biphenyl), TCTA (tri(4-carbazole-9-ylphenyl)amine), TAPC (4,4′-cyclohexylbis[N,N-di(4-methylphenyl)aniline]) and so on.

The electron blocking layer 322 also has good hole transport characteristics, and can be a red electron blocking layer 322, a green electron blocking layer 322, or a blue electron blocking layer 322. They may be aromatic amines or carbazole materials, such as CBP (4,4′-bis(N-carbazole)-1,1′-biphenyl), PCzPA (9-phenyl-3-[4-(10-phenyl-9-anthryl)phenyl]-9 h-carbazole), and the like.

The organic light-emitting layer 330 may be composed of a single light-emitting material, or may include a host material and a dopant material. Optionally, the organic light-emitting layer 330 is composed of a host material and a doping material, the holes injected into the organic light-emitting layer 330 and the electrons injected into the organic light-emitting layer 330 can be compounded on the organic light-emitting layer 330 to form excitons, the excitons transfer energy to the host material, and the host material transfers energy to the doping material so that the doping material can emit light.

The organic light-emitting layer 330 may be a phosphorescent host and a phosphorescent dopant, and may be a fluorescent host and a fluorescent dopant. In addition, each host material may include one material, or may include more than two mixed materials.

Specifically, the host material of the blue organic light-emitting layer may be selected from anthracene derivatives ADN (9,10-di(2-naphthyl)anthracene), MADN (3-tert-butyl-9,10-di(2-naphthyl)anthracene), etc.; the doping material can be pyrene derivatives, fluorene derivatives, perylene derivatives, styrylamine derivatives, metal complexes, etc., such as TBPe (tetrabromophenolphthalein ethyl ester potassium salt), BDAVBi (4,4″-bis[4-(diphenylamino)styryl]biphenyl), DPAVBi (4,4′-bis[4-(di-p-tolylamino)styryl]biphenyl), FIrpic (bis(4,6-difluorophenylpyridine-N,C2)picolinyliridium) and the like.

The green organic light-emitting layer host material may be selected from, for example, coumarin dyes, quinacridone derivatives, polycyclic aromatic hydrocarbons, diamine anthracene derivatives, carbazole derivatives, such as DMQA (N,N′-dimethylquinacridone), BA-NPB (N,N′-di-1-naphthyl-N,N′-diphenyl-[9,9′-bianthracene]-10,10′-diamine; N1,N1′-diphenyl-N1,N1′-dinaphthyl-9,9′-bianthracene-1,1′-diamine), Alq3 (8-hydroxyquinoline aluminum), CBP (4,4′-bis(N-carbazole)-1,1′-biphenyl) and the like. The doping material can be a metal complex, such as Ir(ppy)3 (tri(2-phenylpyridine)iridium|94928-86-6), Ir(ppy)2(acac) (di(2-phenylpyridine)iridium acetylacetonate) and the like.

The host material of the red organic light-emitting layer may be selected from the group consisting of DCM series materials, such as DCJTB (2-{2-tert-butyl-6-[2-(1,1,7,7-tetramethyl-2,3,6,7-tetrahydro-1H,5H-benzo[ij]quinolizin-9-yl) vinyl]-4H-pyran-4-ylidene}malononitrile), DCJTI (2-{2-isopropyl-6-[2-(1,1,7,7-tetramethyl-2,3,6,7-tetrahydro-1H,5H-benzo[ij]quinolizin-9-yl) vinyl]-4H-pyran-4-ylidene}malononitrile), -benzo[ij]quinolizine-9-yl)vinyl]-4H-pyran-4-ylidene)malononitrile) and the like, and the doping material can be a metal complex, such as Ir(piq)2(acac)(bis(1-phenyl-isoquinolinexacetylacetonate)iridium(III)), PtOEP(platinum(II) octaethylporphyrin), Ir(btp)2(acac)(bis(2-(2′-benzothienyl)pyridine-N,C3′)(acetylacetonate)iridium) and the like.

The electron blocking layer 322 and the electron transport layer 350 are generally aromatic heterocyclic compounds, such as imidazole derivatives such as benzimidazole derivatives, imidazopyridine derivatives, benzimidazolephenanthridine derivatives; oxazine derivatives such as pyrimidine derivatives and triazine derivatives; quinoline derivatives, isoquinoline derivatives, phenanthroline derivatives and other compounds containing nitrogen-containing six-membered ring structures (including compounds having phosphine oxide-based substituents on the heterocyclic rings). For example, OXD-7 (2,2′-(1,3-phenyl) di[5-(4-tert-butylphenyl)-1,3,4-oxadiazole]), TAZ (3-(biphenyl-4-yl)-5-(4-tert-butylphenyl)-4-phenyl-4H-1,2,4-triazole), p-EtTAZ (3-(4-tert-butylphenyl)-4-(4-ethylphenyl)-5-(4-biphenylyl)-1,2,4-triazole), BPhen (4,7-diphenyl-1,10-phenanthroline), TPBi (1,3,5-tris(1-phenyl-1H-benzimidazol-2-yl)benzene) and the like.

Further, the light-emitting function layer 300 may also include an electron injection layer 360 disposed between the cathode and the electron transport layer 350. The electron injection layer 360 preferably has a material capable of transporting electrons and has the effect of injecting electrons from the cathode, and has excellent film-forming ability, generally an alkali metal or metal, such as LiF, Yb, Mg, Ca or their compounds.

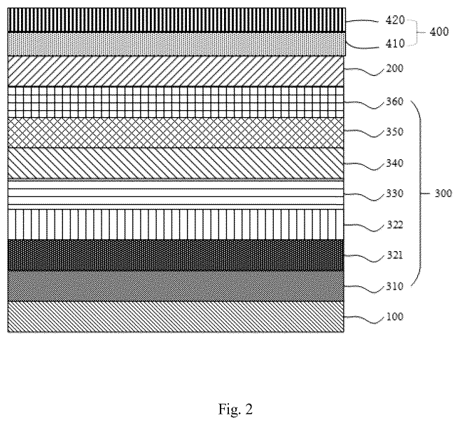

As shown in FIG. 2, in some embodiments of the present disclosure, the capping layer 400 includes a first capping layer 410 and a second capping layer 420 stacked in a direction away from the first electrode layer, the first capping layer 410 includes the first capping layer material, and the second capping layer 420 includes the second capping layer material; wherein the molecular orientation of the first capping layer 410 is between −0.5 and −0.2. Specifically, it may be −0.5, −0.45, −0.4, −0.35, −0.3, −0.25, or −0.2, etc., but is not limited thereto.

The orderly arrangement of molecules is one of the most important properties of micro-molecule organic photoelectric material films. There are usually two types of molecular orientation relative to the substrate: a perpendicular orientation and a horizontal orientation. In organic light-emitting devices, photons are emitted outward from the organic light-emitting layer, and most of them are lost due to total internal reflection. Changing the orientation of organic light-emitting molecules can change the emission angle of the light-emitting dipole, thereby reducing the occurrence of total internal reflection and allowing more photons to be effectively emitted. The horizontal orientation of the light-emitting molecules improves the optical properties of the organic light-emitting device, since the light-emitting direction of the molecules is generally perpendicular to the orientation of the molecules, and thus the ordered molecules in a specific direction also mean a specific light-emitting direction, which can improve the efficiency of the device. The molecular orientation not only influences the optical property of the light-emitting molecules, but also influences the electrical property of the light-emitting molecules, and the molecules with horizontal orientation usually have better electron mobility, and also can improve the efficiency of the device. With the gradual development of the organic photoelectric technology, especially the development of the organic light-emitting device and the organic display technology, the problem of the orientation of the organic molecule gradually causes the attention of people, and the method for measuring and characterizing the orientation of the organic molecule is applied.

For the test of the molecular orientation, one commonly used method is measured by an ellipsometer, and the calculated ordered parameter S is used to characterize the change of the molecular orientation in the thin film, such as the first capping layer. The molecular orientation calculation formula is as follows:

$$S = \frac{3 {cos}^{2} θ - 1}{2} = \frac{{k}_{e} - {k}_{0}}{{k}_{e} + 2 {k}_{0}}$$

θ represents the angle between the molecular dipole axis and the normal line of the substrate plane; kₑ represents the extinction coefficient in the perpendicular direction; k₀ represents the extinction coefficient in the horizontal direction.

The present disclosure further provides a display apparatus, including the aforementioned organic light-emitting device. The display apparatus may be: a mobile phone, a tablet computer, a television, a display, a notebook computer, a digital photo frame or a navigator, or any other product or component with display function.

The organic light-emitting device provided by the present disclosure will be described in detail below in conjunction with specific test data and the like.

### Covering Material Property Test

### Refractive Index

The refractive index is an important physical parameter of the capping layer material, and the magnitude of the refractive index directly determines the optical coupling efficiency of the device.

The refractive index was measured by an ellipsometer. The scanning range of the ellipsometer was 245-1000 nm. A silicon wafer evaporated film was used, and the material film thickness was 50 nm. The refractive index of the first capping layer material at different wavelengths is shown in Table 1, and the refractive index of the second capping layer material at different wavelengths is shown in Table 2.

TABLE 1

| | Wavelength (nm) | | |
|---|---|---|---|
| Compound | 460 | 530 | 620 |
| 1-1 | 2.12 | 2.01 | 1.96 |
| 1-2 | 2.11 | 2.06 | 2.02 |
| 1-3 | 2.05 | 1.99 | 1.93 |
| 1-4 | 2.23 | 2.17 | 2.14 |
| 1-5 | 2.16 | 2.08 | 2.01 |
| 1-6 | 2.36 | 2.29 | 2.17 |

It can be seen from the data in Table 1 that the refractive index of the first capping layer material is higher. Comparing Compound 1-1 and Compound 1-5, it can be seen that the more the number of benzene rings contained in the structure shown in the Chemical Formula 1-1 of the material molecule, the higher the refractive index of the corresponding material molecule. Comparison of Compound 1-5 and Compound 1-6, it can be seen that the more the number of structures shown in chemical formulas 1-2 in the material molecules, the higher the corresponding refractive index of the material molecules.

TABLE 2

| | Wavelength (nm) | | |
|---|---|---|---|
| Compound | 460 | 530 | 620 |
| 3-1 | 1.60 | 1.57 | 1.53 |
| 3-4 | 1.57 | 1.54 | 1.51 |
| 3-10 | 1.56 | 1.53 | 1.51 |
| 3-15 | 1.56 | 1.54 | 1.51 |
| 3-19 | 1.58 | 1.55 | 1.53 |

As can be seen from the data in Table 2, the refractive index of the second capping layer material is low. At a wavelength of 460 nm, the refractive index of the first covering layer material is at least 0.35 greater than that of the second covering layer material, at a wavelength of 530 nm, the refractive index of the first covering layer material is at least 0.42 greater than that of the second covering layer material, and at a wavelength of 620 nm, the refractive index of the first covering layer material is at least 0.4 greater than that of the second covering layer material.

### Absorption Coefficient

The light absorption coefficient was measured by an ellipsometer The scanning range of the ellipsometer was 245-1000 nm. A silicon wafer evaporated film was used, and the material film thickness was 50 nm. The light absorption coefficients of the first capping layer material at different wavelengths are shown in Table 3, and the light absorption coefficients of the second capping layer material at different wavelengths are shown in Table 4.

TABLE 3

| | Wavelength (nm) | | | | |
|---|---|---|---|---|---|
| Compound | 405 | 430 | 460 | 530 | 620 |
| 1-1 | 0.703 | 0.103 | 0.009 | 0.003 | 0.001 |
| 1-2 | 0.685 | 0.009 | 0.008 | 0.002 | 0.001 |
| 1-3 | 0.713 | 0.1 | 0.006 | 0.002 | 0 |
| 1-4 | 0.694 | 0.006 | 0.005 | 0.0001 | 0 |
| 1-5 | 0.682 | 0.008 | 0.007 | 0.003 | 0 |
| 1-6 | 0.723 | 0.009 | 0.004 | 0.001 | 0.001 |

TABLE 4

| | Wavelength (nm) | | | | |
|---|---|---|---|---|---|
| Compound | 405 | 430 | 460 | 530 | 620 |
| 3-1 | 0.516 | 0.112 | 0.005 | 0.001 | 0 |
| 3-4 | 0.485 | 0.009 | 0.006 | 0.001 | 0 |
| 3-10 | 0.513 | 0.1 | 0.003 | 0.001 | 0 |
| 3-15 | 0.494 | 0.007 | 0.004 | 0.0001 | 0 |
| 3-19 | 0.482 | 0.006 | 0.006 | 0.001 | 0 |

As can be seen from the data in Table 3 and Table 4, the first and second capping layer materials of the present disclosure have a particularly good absorption at a wavelength of 430 nm or less, at a wavelength of 430 nm or more, and at a wavelength of 430 nm or more, the absorption is almost very small. Such a material has a particularly small absorption of red light, green light, and blue light, which will not affect the light output of the device, and has a strong absorption at a wavelength of 430 nm or shorter, which can fully absorb external ultraviolet light and prevent ultraviolet light from damaging the light-emitting device, thereby improving the performance of the device.

### Stability

The glass transition temperature (Tg) determines the thermal stability of the material in the evaporation process, and the higher the Tg, the better the thermal stability of the material.

The measuring instrument was a DSC differential scanning calorimeter. The test atmosphere was nitrogen, the heating rate was 10 degrees centigrade/min, and the temperature range was 50 to 300 degrees centigrade. The glass transition temperature (Tg) measured for the first capping material and the second capping material of the present disclosure is shown in Table 5.

TABLE 5

| Compound | Tg (° C.) | Compound | Tg (° C.) |
|---|---|---|---|
| 1-1 | 132 | 3-1 | 138 |
| 1-2 | 136 | 3-4 | 140 |
| 1-3 | 137 | 3-10 | 139 |
| 1-4 | 133 | 3-15 | 135 |
| 1-5 | 135 | 3-19 | 134 |
| 1-6 | 136 | — | — |

It can be seen from the data in Table 5 that the first capping layer material and the second capping layer material of the present disclosure have higher glass transition temperature, which is beneficial for improving the thermodynamic stability of the material. During the evaporation process, the material does not undergo cracking changes, which is a basic condition for the material to be evaporated and maintain a long life.

### Other Film Layer Material Physical Property Test

### Refractive Index

The measuring method refers to the measurement of the refractive index of the capping layer material. The refractive indices of the hole transport layer (HTL), the organic light-emitting layer (EML) and the electron transport layer (ETL) are shown in Table 6.

TABLE 6

| | Wavelength (nm) | | |
|---|---|---|---|
| Compound | 460 | 530 | 620 |
| HTL | 1.93 | 1.84 | 1.8 |
| ETL | 1.59 | 1.81 | 1.78 |
| BEML | 1.74 | 1.69 | 1.66 |
| GEML | 1.77 | 1.68 | 1.67 |
| REML | 1.75 | 1.69 | 1.65 |

BEML, GEML, and REML refer to the organic light-emitting layer 330 of the blue light device, the organic light-emitting layer 330 of the green light device, and the organic light-emitting layer 330 of the red light device, respectively.

The structure of the material selected for each film layer can refer to Table 7.

### Device Examples

The preparation process of the blue light device according to the Example 1 was as follows: cleaning and drying the prepared ITO substrate; evaporating the hole injection layer HIL material, the hole transport layer HTL material and the electron blocking layer EBL material on the anode in sequence; then evaporating the organic light-emitting layer BH1 material; evaporating an electronic barrier layer HBL material, an electron transport layer ETL material and an electronic injection layer EIL material on the organic light-emitting layer; and then evaporating the cathode; evaporating a first capping layer material with high refractive index on the cathode; evaporating the second capping layer material of the present disclosure on the first capping layer, as the second capping layer. The device structure was: I ITO/HIL(10 nm)/HTL(100 nm)/EBL(10 nm)/BH:BD(20 nm, 5%)/HBL(5 nm)/ETL:LIQ(30 nm, 50%)/EIL(Yb)(1 nm)/Mg:Ag 13 nm/CPL1 200 nm/CPL2 300 nm.

### Example 2-4 Preparation Process

The first capping layer material and the second capping layer material in Example 1 were replaced with the data in Table 8, and others were unchanged.

### Comparative Example 1 Preparation Process

The first capping layer material in Example 1 was replaced with CP1, and the second capping layer material was removed, and the other materials were unchanged.

The material structures in the examples were shown in Table 7.

TABLE 7

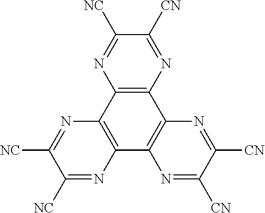 [SMILES: N#Cc1nc2c3nc(C#N)c(C#N)nc3c3nc(C#N)c(C#N)nc3c2nc1C#N]

HIL

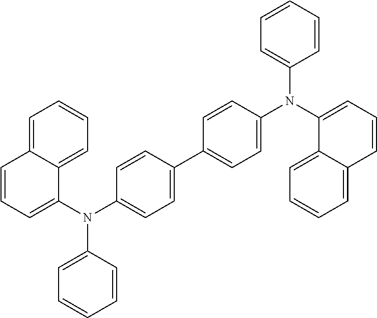 [SMILES: c1ccc(N(c2ccc(-c3ccc(N(c4ccccc4)c4cccc5ccccc45)cc3)cc2)c2cccc3ccccc23)cc1]

HTL

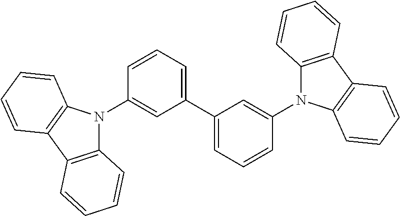 [SMILES: c1cc(-c2cccc(-n3c4ccccc4c4ccccc43)c2)cc(-n2c3ccccc3c3ccccc32)c1]

EBL

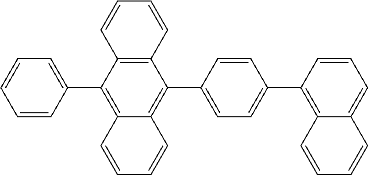 [SMILES: c1ccc(-c2c3ccccc3c(-c3ccc(-c4cccc5ccccc45)cc3)c3ccccc23)cc1]

BH

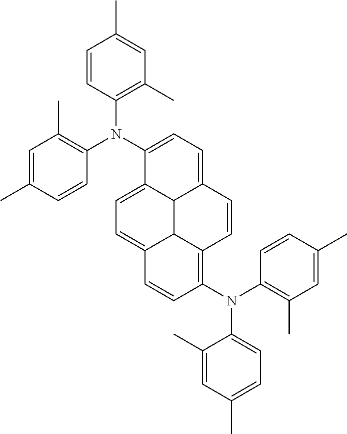

BD

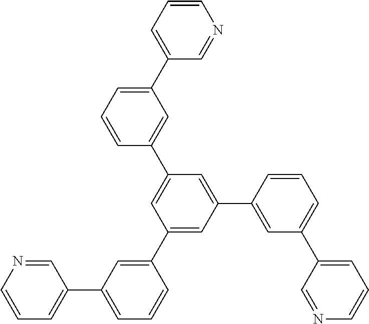 [SMILES: c1cncc(-c2cccc(-c3cc(-c4cccc(-c5cccnc5)c4)cc(-c4cccc(-c5cccnc5)c4)c3)c2)c1]

HBL

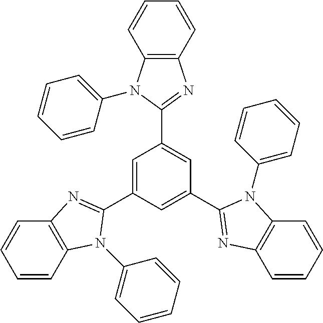 [SMILES: c1ccc(-n2c(-c3cc(-c4nc5ccccc5n4-c4ccccc4)cc(-c4nc5ccccc5n4-c4ccccc4)c3)nc3ccccc32)cc1]

ETL

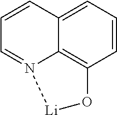

LIQ

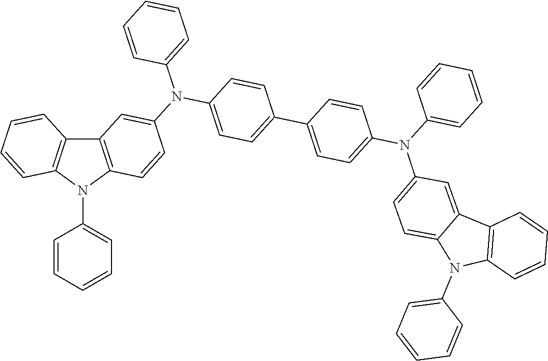 [SMILES: c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1]

CP1

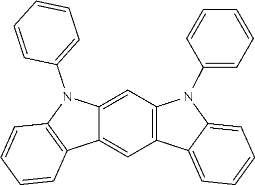 [SMILES: c1ccc(-n2c3ccccc3c3cc4c5ccccc5n(-c5ccccc5)c4cc32)cc1]

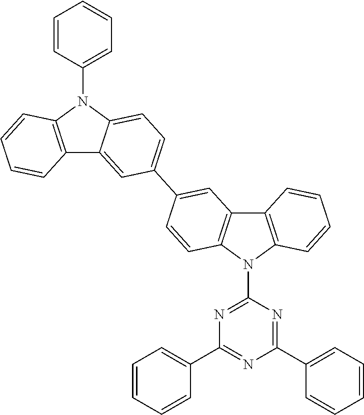 [SMILES: c1ccc(-c2nc(-c3ccccc3)nc(-n3c4ccccc4c4cc(-c5ccc6c(c5)c5ccccc5n6-c5ccccc5)ccc43)n2)cc1]

RH (premix)

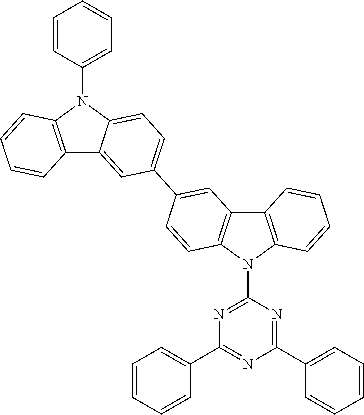 [SMILES: c1ccc(-c2nc(-c3ccccc3)nc(-n3c4ccccc4c4cc(-c5ccc6c(c5)c5ccccc5n6-c5ccccc5)ccc43)n2)cc1]

ED

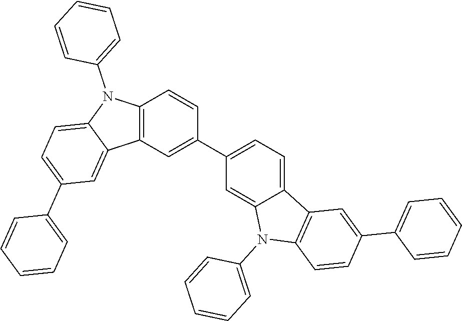 [SMILES: c1ccc(-c2ccc3c(c2)c2cc(-c4ccc5c6cc(-c7ccccc7)ccc6n(-c6ccccc6)c5c4)ccc2n3-c2ccccc2)cc1]

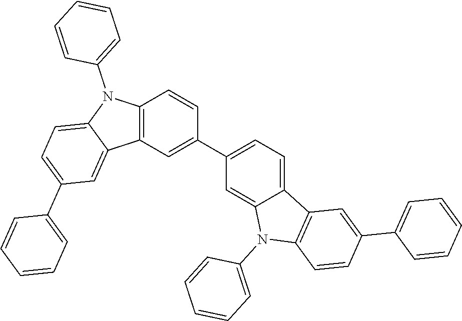 [SMILES: c1ccc(-c2ccc3c(c2)c2cc(-c4ccc5c6cc(-c7ccccc7)ccc6n(-c6ccccc6)c5c4)ccc2n3-c2ccccc2)cc1]

BH (premix)

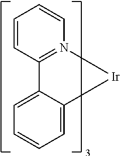

GD

For the organic light-emitting device prepared as above, the properties of the device were analyzed under the condition of 20 mA/cm², and the results are shown in Table 8.

TABLE 8

| | The | The | The properties of the device | | |
|---|---|---|---|---|---|
| | first | second | | | Life |
| | capping | capping | | | (LT95@1000 |
| Example | material | material | Voltage | Efficiency | nit) |
| Example 1 | 1-1 | 3-1 | 97% | 107.11% | 109.36% |
| Example 2 | 1-1 | 3-4 | 97% | 104.82% | 108.01% |
| Example 3 | 1-2 | 3-1 | 96% | 104.28% | 106.77% |
| Example 4 | 1-2 | 3-4 | 96% | 103.97% | 106.59% |
| Comparative | CP1 | none | 100% | 100% | 100% |
| Example 1 | | | | | |

The values in Table 8 are the percentages of the examples relative to the comparative example, with reference to the comparative example. In comparison with the light-emitting device prepared in Comparative Example 1, the light-emitting devices prepared in embodiments 1 to 4 using the disclosed compound as the capping layer 400 have lower driving voltage, higher luminous efficiency and longer life.

It should be understood that the present disclosure does not limit its application to the detailed structure and arrangement of the components set forth in this specification. The present disclosure can have other embodiments, and can be implemented and executed in a variety of ways. The foregoing variations and modifications fall within the scope of the present disclosure. It should be understood that the present disclosure as disclosed and defined herein extends to all alternative combinations of two or more individual features mentioned or apparent in the text and/or the accompanying drawings. All these different combinations constitute a number of alternative aspects of the present disclosure. Embodiments of this specification illustrate the best modes known for carrying out the present disclosure and will enable those skilled in the art to make use of the present disclosure.

1. An organic light-emitting device, comprising a first electrode layer, a light-emitting functional layer, a second electrode layer and a capping layer sequentially stacked, wherein the capping layer comprises a first capping layer material and a second capping layer material;
The first capping layer material and the second capping layer material satisfy:
$${n}_{1} ( {λ}_{1} ) - {n}_{2} ( {λ}_{1} ) \geq 0.2 , 440 nm \leq {λ}_{1} \leq 480 nm ;$$
$${n}_{1} ( {λ}_{2} ) - {n}_{2} ( {λ}_{2} ) \geq 0.1 , 500 nm \leq {λ}_{2} \leq 550 nm ;$$
$${n}_{1} ( {λ}_{3} ) - {n}_{2} ( {λ}_{3} ) \geq 0.1 , 600 nm \leq {λ}_{3} \leq 640 nm ;$$
the light-emitting functional layer comprises a hole transport layer, an organic light-emitting layer and an electron transport layer sequentially stacked in a direction away from the first electrode layer, and the hole transport layer, the organic light-emitting layer and the electron transport layer satisfy:
$$0.1 \leq {n}_{3} ( {λ}_{1} ) - {n}_{4} ( {λ}_{1} ) \leq 0.8 ; 0.1 \leq {n}_{3} ( {λ}_{2} ) - {n}_{4} ( {λ}_{2} ) \leq 0.8 ;$$
$$0.1 \leq {n}_{3} ( {λ}_{3} ) - {n}_{4} ( {λ}_{3} ) \leq 0.8 ;$$
$$0.1 \leq {n}_{5} ( {λ}_{1} ) - {n}_{4} ( {λ}_{1} ) \leq 0.8 ; 0.1 \leq {n}_{5} ( {λ}_{2} ) - {n}_{4} ( {λ}_{2} ) \leq 0.8 ;$$
$$0.1 \leq {n}_{5} ( {λ}_{3} ) - {n}_{4} ( {λ}_{3} ) \leq 0.8 ;$$
wherein, λ₁, λ₂, and λ₃ represent different wavelength ranges of light respectively;
n₁ represents the refractive index of the first capping layer material, and n₂ represents the refractive index of the second capping layer material;
n₃ represents the refractive index of the hole transport layer, n₄ represents the refractive index of the organic light emitting layer, and n₅ represents the refractive index of the electron transport layer.

2. The organic light-emitting device according to claim 1, wherein the first capping layer material and the second capping layer material satisfy:
$${k}_{1} ( {λ}_{4} ) - {k}_{2} ( {λ}_{5} ) \geq 0.1 , {λ}_{4} = 405 nm , {λ}_{5} = 430 nm ;$$
$$0.8 \leq [ {k}_{2} ( {λ}_{4} ) - {k}_{2} ( {λ}_{5} ) ] / [ {k}_{1} ( {λ}_{4} ) - {k}_{1} ( {λ}_{5} ) ] \leq 1 ;$$
$${k}_{1} ( {λ}_{6} ) \leq 0.08 ; {k}_{2} ( {λ}_{6} ) \leq 0.08 , {λ}_{6} \geq 430 nm ;$$
wherein, λ₄, λ₅, and λ₆ represent different wavelength ranges of light respectively;
k₁ represents the absorption coefficient of the first capping layer material, and k₂ represents the absorption coefficient of the second capping layer material.

3. The organic light-emitting device according to claim 1, wherein the first capping layer material is selected from a structure shown in Chemical Formula 1, 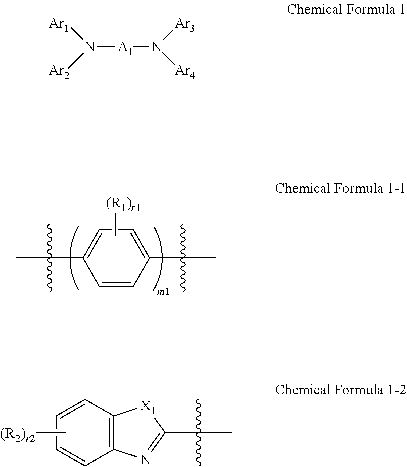
Wherein, 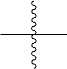
represents a chemical bond;
the group A₁ is selected from the structure represented by the Chemical Formula 1-1;
at least one of Ar₁, Ar₂, Ar₃ and Ar₄ is selected from the structure represented by Chemical Formula 1-2, when Ar₁, Ar₂, Ar₃ and Ar₄ are not selected from the structure represented by Chemical Formula 1-2, Ar₁, Ar₂, Ar₃ and Ar₄ are each independently selected from hydrogen, deuterium, halogen, alkyl with 1-6 carbon atoms, substituted or unsubstituted aryl with 6-20 carbon atoms, substituted or unsubstituted heteroaryl with 5-30 carbon atoms;
X₁ is selected from O or S;
R₁ is selected from hydroxyl, alkyl with 1-4 carbon atoms and aryl with 6-12 carbon atoms;
R₂ is selected from alkyl with 1-4 carbon atoms and aryl with 6-12 carbon atoms;
r1 is the number of R₁, and r1 is selected from 0, 1, 2, 3 or 4;
r2 is the number of R₂, and r2 is selected from 0, 1, 2, 3 or 4;
m1 is selected from 1, 2 or 3, and when m1 is more than 1, two adjacent benzene rings can be connected to form a ring;
the substituents on Ar₁, Ar₂, Ar₃, and Ar₄ are each independently selected from deuterium, halogen, alkyl with 1-4 carbon atoms, aryl with 6-12 carbon atoms, heteroaryl with 5-12 carbon atoms.

4. The organic light-emitting device according to claim 3, wherein the group M is selected from the group consisting of:

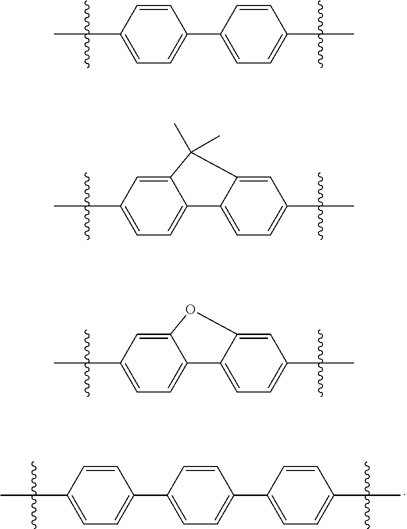 [SMILES: *c1ccc(-c2ccc(*)cc2)cc1 ; *c1ccc2c(c1)C(C)(C)c1cc(*)ccc1-2 ; *c1ccc2c(c1)oc1cc(*)ccc12 ; *c1ccc(-c2ccc(-c3ccc(*)cc3)cc2)cc1]

5. The organic light-emitting device according to claim 3, wherein Ar₁, Ar₂, Ar₃, and Ar₄ are each independently selected from the group consisting of hydrogen, substituted or unsubstituted phenyl, substituted or unsubstituted biphenyl, substituted or unsubstituted dibenzofuranyl, substituted or unsubstituted fluorenyl, and a structure represented by Chemical Formula 1-2;
the substituents on Ar₁, Ar₂, Ar₃ and Ar₄ are independently selected from deuterium, halogen, methyl, phenyl and pyridyl.

6. The organic light-emitting device according to claim 1, wherein the second capping layer material is selected from an inorganic material or a structure represented by Chemical Formula 2, 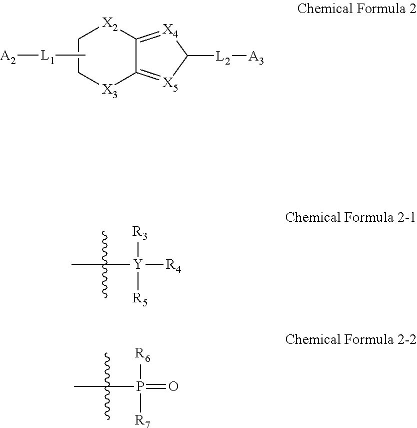
wherein, 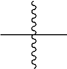
represents a chemical bond;
A₂ and A₃ are each independently selected from a structure represented by Chemical Formula 2-1 or Chemical Formula 2-2;
X₂ and X₃ are each independently selected from B(R₈), C(R₉R₁₀), O and S;
X₄ and X₅ are each independently selected from CH and N;
Y is selected from C and Si;
L₁ and L₂ are independently selected from substituted or unsubstituted arylidene with 6-20 carbon atoms;
R₃, R₄, R₅, R₆, R₇ are each independently selected from substituted or unsubstituted aryl having 6-20 carbon atoms;
R₈, R₉, R₁₀ are each independently selected from hydrogen, alkyl with 1-6 carbon atoms, substituted or unsubstituted aryl with 6-20 carbon atoms;
the substituents on L₁, L₂, R₃, R₄, R₅, R₆, R₇, R₈, R₉ and R₁₀ are independently selected from deuterium, halogen and alkyl with 1-6 carbon atoms;
the structure represented by Chemical Formula 2-1 or Chemical Formula 2-2 contains tert-butyl.

7. The organic light-emitting device according to claim 6, wherein L₁, L₂ are each independently selected from substituted or unsubstituted phenylene groups.

8. The organic light-emitting device according to claim 6, wherein R₃, R₄, R₅, R₆, R₇ are each independently selected from substituted or unsubstituted phenyl;
the substituents on R₃, R₄, R₅, R₆ and R₇ are independently selected from methyl, ethyl and tert-butyl.

9. The organic light-emitting device according to claim 1, wherein the light-emitting functional layer further comprises an electron blocking layer and a hole blocking layer, the electron blocking layer is disposed between the hole transport layer and the organic light-emitting layer, and the hole blocking layer is disposed between the organic light-emitting layer and the electron transport layer;
the hole blocking layer and the electron transport layer satisfy:
$$0.4 eV \leq LUMO ( HBL ) - LUMO ( ETL ) \leq 1 eV ;$$
the electron blocking layer and the hole transport layer satisfy:
$$0.3 eV \leq HOMO ( HTL ) - HOMO ( EBL ) \leq 1 eV ;$$
wherein LUMO (HBL) is the lowest unoccupied molecular orbital LUMO energy level of the hole blocking layer material, and LUMO (ETL) is the lowest unoccupied molecular orbital LUMO energy level of the electron transport layer material;
HOMO (HTL) is the highest occupied molecular orbital HOMO energy level of the hole transport layer material, and HOMO (EBL) is the highest occupied molecular orbital HOMO energy level of the electron blocking layer material.

10. The organic light-emitting device according to claim 9, wherein the organic light-emitting layer material comprises a host material and a dopant material;
the host material of the organic light-emitting layer and the hole blocking layer satisfy:
$$T 1 ( HBL ) > T 1 ( Host ) ;$$
the host material of the organic light-emitting layer and the electron blocking layer satisfy:
$$T 1 ( EBL ) > T 1 ( Host ) ;$$
wherein T1(HBL) is the lowest triplet energy of the hole blocking layer material, T1 (EBL) is the lowest triplet energy of the electron blocking layer material, and T1(Host) is the lowest triplet energy of the organic light-emitting layer host material.

11. The organic light-emitting device according to claim 10, wherein the host material of the organic light-emitting layer and the doping material of the organic light-emitting layer satisfy:
$$T 1 ( Dopant ) > T 1 ( Host ) ;$$
$$S 1 ( Host ) > S 1 ( Dopant ) ;$$
wherein T1(Dopant) is the lowest triplet excitation energy of the doped material of the organic light-emitting layer, S1(Host) is the lowest singlet excitation energy of the host material of the organic light-emitting layer, S1(Dopant) is the lowest singlet excitation energy of the doping material of the organic light-emitting layer.

12. The organic light-emitting device according to claim 1, wherein the hole mobility and the electron mobility of the organic light-emitting layer satisfy:
$$0.01 < μ h ( EML ) / μ e ( EML ) \leq 100 ;$$
wherein, μh(EML) is the hole mobility of the organic light-emitting layer, and μe(EML) is the electron mobility of the organic light-emitting layer.

13. The organic light-emitting device according to claim 1, wherein the light-emitting functional layer further comprises a hole injection layer disposed between the first electrode layer and the hole transport layer;
the resistivity of the hole injection layer is not less than 100 Ω·m.

14. The organic light-emitting device according to claim 1, wherein the capping layer comprises a first capping layer and a second capping layer stacked in a direction away from the first electrode layer, the first capping layer comprises the first capping layer material, and the second capping layer comprises the second capping layer material;
wherein the molecular orientation of the first capping layer is between −0.5 and −0.2.

15. The organic light-emitting device according to claim 6, wherein the inorganic material is selected from one or more of metal compounds, non-metal compounds, metals, and metal alloys.

16. A display apparatus, comprising an organic light-emitting device;
wherein, the organic light-emitting device comprises a first electrode layer, a light-emitting functional layer, a second electrode layer and a capping layer sequentially stacked, wherein the capping layer comprises a first capping layer material and a second capping layer material;
The first capping layer material and the second capping layer material satisfy:
$${n}_{1} ( {λ}_{1} ) - {n}_{2} ( {λ}_{1} ) \geq 0.2 , 440 nm \leq {λ}_{1} \leq 480 nm ;$$
$${n}_{1} ( {λ}_{2} ) - {n}_{2} ( {λ}_{2} ) \geq 0.1 , 500 nm \leq {λ}_{2} \leq 550 nm ;$$
$${n}_{1} ( {λ}_{3} ) - {n}_{2} ( {λ}_{3} ) \geq 0.1 , 600 nm \leq {λ}_{3} \leq 640 nm ;$$
the light-emitting functional layer comprises a hole transport layer, an organic light-emitting layer and an electron transport layer sequentially stacked in a direction away from the first electrode layer, and the hole transport layer, the organic light-emitting layer and the electron transport layer satisfy:
$$0.1 \leq {n}_{3} ( {λ}_{1} ) - {n}_{4} ( {λ}_{1} ) \leq 0.8 ; 0.1 \leq {n}_{3} ( {λ}_{2} ) - {n}_{4} ( {λ}_{2} ) \leq 0.8 ;$$
$$0.1 \leq {n}_{3} ( {λ}_{3} ) - {n}_{4} ( {λ}_{3} ) \leq 0.8 ;$$
$$0.1 \leq {n}_{5} ( {λ}_{1} ) - {n}_{4} ( {λ}_{1} ) \leq 0.8 ; 0.1 \leq {n}_{5} ( {λ}_{2} ) - {n}_{4} ( {λ}_{2} ) \leq 0.8 ;$$
$$0.1 \leq {n}_{5} ( {λ}_{3} ) - {n}_{4} ( {λ}_{3} ) \leq 0.8 ;$$
wherein, λ₁, λ₂, and λ₃ represent different wavelength ranges of light respectively;
n₁ represents the refractive index of the first capping layer material, and n₂ represents the refractive index of the second capping layer material;
n₃ represents the refractive index of the hole transport layer, n₄ represents the refractive index of the organic light emitting layer, and n₅ represents the refractive index of the electron transport layer.

17. The display apparatus according to claim 16, wherein the first capping layer material and the second capping layer material satisfy:
$${k}_{1} ( {λ}_{4} ) - {k}_{2} ( {λ}_{5} ) \geq 0.1 , {λ}_{4} = 405 nm , {λ}_{5} = 430 nm ;$$
$$0.8 \leq [ {k}_{2} ( {λ}_{4} ) - {k}_{2} ( {λ}_{5} ) ] / [ {k}_{1} ( {λ}_{4} ) - {k}_{1} ( {λ}_{5} ) ] \leq 1 ;$$
$${k}_{1} ( {λ}_{6} ) \leq 0.08 ; {k}_{2} ( {λ}_{6} ) \leq 0.08 , {λ}_{6} \geq 430 nm ;$$
wherein, λ₄, λ₅, and λ₆ represent different wavelength ranges of light respectively;
k₁ represents the absorption coefficient of the first capping layer material, and k₂ represents the absorption coefficient of the second capping layer material.

18. The display apparatus according to claim 16, wherein the light-emitting functional layer further comprises an electron blocking layer and a hole blocking layer, the electron blocking layer is disposed between the hole transport layer and the organic light-emitting layer, and the hole blocking layer is disposed between the organic light-emitting layer and the electron transport layer:
the hole blocking layer and the electron transport layer satisfy:
$$0.4 eV \leq LUMO ( HBL ) - LUMO ( ETL ) \leq 1 eV ;$$
the electron blocking layer and the hole transport layer satisfy:
$$0.3 eV \leq HOMO ( HTL ) - HOMO ( EBL ) \leq 1 eV ;$$
wherein LUMO (HBL) is the lowest unoccupied molecular orbital LUMO energy level of the hole blocking layer material, and LUMO (ETL) is the lowest unoccupied molecular orbital LUMO energy level of the electron transport layer material;
HOMO (HTL) is the highest occupied molecular orbital HOMO energy level of the hole transport layer material, and HOMO (EBL) is the highest occupied molecular orbital HOMO energy level of the electron blocking layer material.

19. The display apparatus according to claim 18, wherein the organic light-emitting layer material comprises a host material and a dopant material:
the host material of the organic light-emitting layer and the hole blocking layer satisfy:
$$T 1 ( HBL ) > T 1 ( Host ) ;$$
the host material of the organic light-emitting layer and the electron blocking layer satisfy:
$$T 1 ( EBL ) > T 1 ( Host ) ;$$
wherein T1(HBL) is the lowest triplet energy of the hole blocking layer material, T1(EBL) is the lowest triplet energy of the electron blocking layer material, and T1(Host) is the lowest triplet energy of the organic light-emitting layer host material.

20. The display apparatus according to claim 19, wherein the host material of the organic light-emitting layer and the doping material of the organic light-emitting layer satisfy:
$$T 1 ( Dopant ) > T 1 ( Host ) ;$$
$$S 1 ( Host ) > S 1 ( Dopant ) ;$$
wherein T1(Dopant) is the lowest triplet excitation energy of the doped material of the organic light-emitting layer, S1(Host) is the lowest singlet excitation energy of the host material of the organic light-emitting layer, S1(Dopant) is the lowest singlet excitation energy of the doping material of the organic light-emitting layer.
